(19) United States
(12) Patent Application Publication
(10) Pub. No.: US 2024/0164083 A1
(43) Pub. Date: May 16, 2024

(54) MICROELECTRONIC DEVICES INCLUDING STAIRCASE STRUCTURES, RELATED MEMORY DEVICES, ELECTRONIC SYSTEMS, AND METHODS

(71) Applicant: Micron Technology, Inc., Boise, ID (US)

(72) Inventor: Yuichi Yokoyama, Boise, ID (US)

(21) Appl. No.: 18/054,291

(22) Filed: Nov. 10, 2022

(51) Int. Cl. H01L 27/108

(52) U.S. Cl. CPC H01L 27/10805; H01L 27/1085

(57) ABSTRACT

A microelectronic device comprises a stack structure comprising an array region comprising first conductive structures vertically spaced from one another, and a staircase region horizontally neighboring the array region and comprising second conductive structures vertically spaced from one another and coupled to the first conductive structures. The second conductive structures individually comprise portions extending in a first horizontal direction, and additional portions extending in a second horizontal direction transverse to the first horizontal direction. The staircase region comprises staircase structures having steps partially defined by edges of the second conductive structures. Some of the steps extend in the first horizontal direction and some others of the steps extend in the second horizontal direction. Related memory devices, electronic systems, and methods are also described.

### TECHNICAL FIELD

The disclosure, in various embodiments, relates generally to the field of microelectronic device design and fabrication. More specifically, the disclosure relates to microelectronic devices including staircase structures partially defined by conductive structures, and to related memory devices, electronic systems, and methods.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, volatile memory devices, such as dynamic random access memory (DRAM) devices; and non-volatile memory devices such as NAND Flash memory devices. A typical memory cell of a DRAM device includes one access device, such as a transistor, and one memory storage structure, such as a capacitor. Modern applications for semiconductor devices can employ significant quantities of memory cells, arranged in memory arrays exhibiting rows and columns of the memory cells. The memory cells may be electrically accessed through digit lines (e.g., bit lines, data lines) and word lines (e.g., access lines) arranged along the rows and columns of the memory cells of the memory arrays. Memory arrays can be two-dimensional (2D) so as to exhibit a single deck (e.g., a single tier, a single level) of the memory cells, or can be three-dimensional (3D) so as to exhibit multiple decks (e.g., multiple levels, multiple tiers) of the memory cells.

Vertical memory array architectures generally include electrical connections between the conductive structures of the tiers of the conductive stack structure(s) of the memory device and access lines (e.g., word lines) so that the memory cells of the vertical memory array can be uniquely selected for writing, reading, or erasing operations. One method of forming such an electrical connection includes forming so-called “staircase” (or “stair step”) structures at edges (e.g., horizontal ends) of the tiers of the conductive stack structure(s) of the memory device. The staircase structure includes individual “steps” defining contact regions of the conductive structures, upon which conductive contact structures can be positioned to provide electrical access to the conductive structures.

As the size of the memory cells has decreased, the density and complexity of the memory array have increased. With the increased density of memory cells within the memory array, the density of the conductive interconnect structures configured to facilitate operation of the memory cells has also increased. For example, the spacing between neighboring conductive interconnect structures has decreased with the increased density of memory cells of the memory array. However, the increased density of the conductive interconnect structures presents difficulties in adequately forming conductive interconnect structures in electrical communication with the memory cells.

### BRIEF DESCRIPTION OF THE DRAWINGS

FIGS. 1A through 1C are a simplified, partial top-down view (FIG. 1A) and simplified, partial cross-sectional views (FIGS. 1B and 1C) of a microelectronic device, in accordance with embodiments of the disclosure;

FIGS. 2A through 2K are simplified, partial perspective views (FIGS. 2A through 2D and 2F), simplified, partial top-down views (FIGS. 2E, 2G, 2I, and 2J), and simplified, partial cross-sectional views (FIGS. 2H and 2K) illustrating a method of forming a microelectronic device, in accordance with embodiments of the disclosure; and

FIG. 3 is a schematic block diagram of an electronic system, in accordance with an embodiment of the disclosure.

### DETAILED DESCRIPTION

The following description provides specific details, such as material types, material thicknesses, and processing conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete process flow for manufacturing a microelectronic device (e.g., a semiconductor device, a memory device), apparatus, or electronic system, or a complete microelectronic device, apparatus, or electronic system. The structures described below do not form a complete microelectronic device, apparatus, or electronic system. Only those process acts and structures necessary to understand the embodiments described herein are described in detail below. Additional acts to form a complete microelectronic device, apparatus, or electronic system from the structures may be performed by conventional techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the claims. The drawings are not necessarily to scale. Additionally, elements common between figures may retain the same numerical designation.

As used herein, the term “memory device” means and includes microelectronic devices exhibiting memory functionality, but not necessary limited to memory functionality. By way of example only, the term “memory device” means and includes not only conventional memory (e.g., conventional volatile memory, such as conventional DRAM; conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, the terms “longitudinal,” “vertical,” “lateral,” and “horizontal” are in reference to a major plane of a substrate (e.g., base material, base structure, base construction, etc.) in or on which one or more structures and/or features are formed and are not necessarily defined by Earth's gravitational field. A “lateral” or “horizontal” direction is a direction that is substantially parallel to the major plane of the substrate, while a “longitudinal” or “vertical” direction is a direction that is substantially perpendicular to the major plane of the substrate. The major plane of the substrate is defined by a surface of the substrate having a relatively large area compared to other surfaces of the substrate. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, materials, structures, devices) described as “neighboring” one another means and includes features of the disclosed identity (or identities) that are located most proximate (e.g., closest to) one another. Additional features (e.g., additional regions, additional materials, additional structures, additional devices) not matching the disclosed identity (or identities) of the “neighboring” features may be disposed between the “neighboring” features. The “neighboring” features may be positioned directly adjacent one another, such that no other feature intervenes between the “neighboring” features; or the “neighboring” features may be positioned indirectly adjacent one another, such that at least one feature having an identity other than that associated with at least one of the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, the term “intersection” means and includes a location at which two or more features (e.g., regions, structures, materials, devices) or, alternatively, two or more portions of a single feature meet. For example, an intersection between a first feature extending in a first direction (e.g., an X-direction) and a second feature extending in a second direction (e.g., a Y-direction) different than the first direction may be the location at which the first feature and the second feature meet.

As used herein, the term “pitch” between two neighboring features refers to a distance between corresponding locations (e.g., points) within the two neighboring features.

As used herein, reference to an element as being “on” or “over” another element means and includes the element being directly on top of, directly adjacent to (e.g., directly laterally adjacent to, directly vertically adjacent to), directly underneath, or in direct contact with the other element. It also includes the element being indirectly on top of, indirectly adjacent to (e.g., indirectly laterally adjacent to, indirectly vertically adjacent to), indirectly underneath, or near the other element, with other elements present therebetween. In contrast, when an element is referred to as being “directly on” or “directly adjacent to” another element, there are no intervening elements present.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped, etc.) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the term “configured” refers to a size, shape, material composition, orientation, and arrangement of one or more of at least one structure and at least one apparatus facilitating operation of one or more of the structure and the apparatus in a predetermined way.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Jr), nickel (Ni), palladium (Pa), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively doped polysilicon, conductively doped germanium (Ge), conductively doped silicon germanium (SiGe)). In addition, a “conductive structure” means and includes a structure formed of and including a conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including an insulative material.

Unless otherwise specified, materials described herein may be formed by conventional techniques including, but not limited to, spin coating, blanket coating, chemical vapor deposition (CVD), atomic layer deposition (ALD), plasma enhanced ALD, physical vapor deposition (PVD), plasma enhanced chemical vapor deposition (PECVD), or low pressure chemical vapor deposition (LPCVD). Alternatively, the materials may be grown in situ. Depending on the specific material to be formed, the technique for depositing or growing the material may be selected by a person of ordinary skill in the art. The removal of materials may be accomplished by any suitable technique including, but not limited to, etching, abrasive planarization (e.g., chemical-mechanical planarization), or other known methods unless the context indicates otherwise.

According to embodiments described herein, a microelectronic device (e.g., a memory device, such as a 3D DRAM memory device) includes a stack structure comprising an array region comprising first conductive structures (e.g., access lines, digit lines) vertically spaced from one another, and a staircase region horizontally neighboring the array region and comprising second conductive structures (e.g., additional access lines, additional digit lines) vertically spaced from one another and coupled to the first conductive structures. The second conductive structures may individually horizontally extend in a multi-directional path (e.g., a non-linear horizontal path). For example, the second conductive structures individually comprise portions extending in a first horizontal direction, and additional portions extending in a second horizontal direction transverse to the first horizontal direction. The staircase region includes staircase structures having steps partially defined by edges of the second conductive structures. Some of the steps extend in the first horizontal direction and some others of the steps extend in the second horizontal direction.

In some embodiments, the staircase structures have at least partially curved horizontal cross-sectional shapes, such as closed curve (e.g., partially elliptical) horizontal cross-sectional shapes, and are arranged relative to one another a weave pattern (e.g., a hexagonal pattern, such as a hexagonal close-packed pattern). The microelectronic device includes conductive contacts on individual steps of the staircase structures. The conductive contacts of individual staircase structures are aligned with one another in rows extending in the second horizontal direction, and the individual staircase structures comprise two or more of the conductive contacts on each vertical level of the steps. Forming the microelectronic device to include staircase structures having at least partially curved horizontal cross-sectional shapes facilitates reducing an area of the microelectronic device as compared to conventional microelectronic devices. In addition, forming the staircase structures of the disclosure may provide a larger process margin (e.g., an increased area) for forming the conductive contact structures on the steps thereof and/or space for forming a greater quantity of the conductive contact structures within the staircase region. Further, forming the staircase structures of the disclosure in the weave pattern, as well as the second conductive structures of the disclosure, may provide increased support within the microelectronic device.

Further, forming the conductive structures of the disclosure within the staircase region facilitates an optimized use of area of the staircase region such that an area allocated to the staircase structures is reduced and reliability of the microelectronic device structure is improved. In addition, the second conductive structures may be substantially continuous with the first conductive structures at each vertical level of the stack structure and may be formed during formation of the first conductive structures. Accordingly, manufacturing processes may be simplified and manufacturing costs may be reduced by forming the second conductive structures and the first conductive structures in a single processing act. The methods of the disclosure, therefore, may reduce or eliminate process acts that are otherwise utilized in many conventional microelectronic devices to form conductive structures and staircase structures so as to simplify manufacturing processes and reduce complexity of the microelectronic device. Further, the multi-directional horizontal pathing of the second conductive structures may substantially mitigate capacitive coupling between horizontally neighboring second conductive structures, allowing for improved electrical conductivity during use and operation of the microelectronic device compared to conventional microelectronic devices.

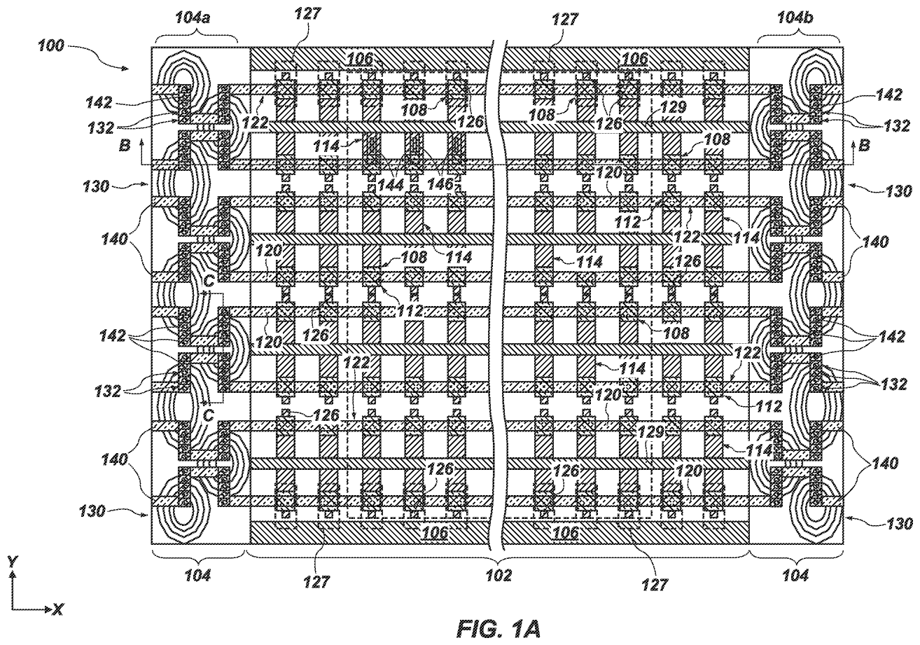

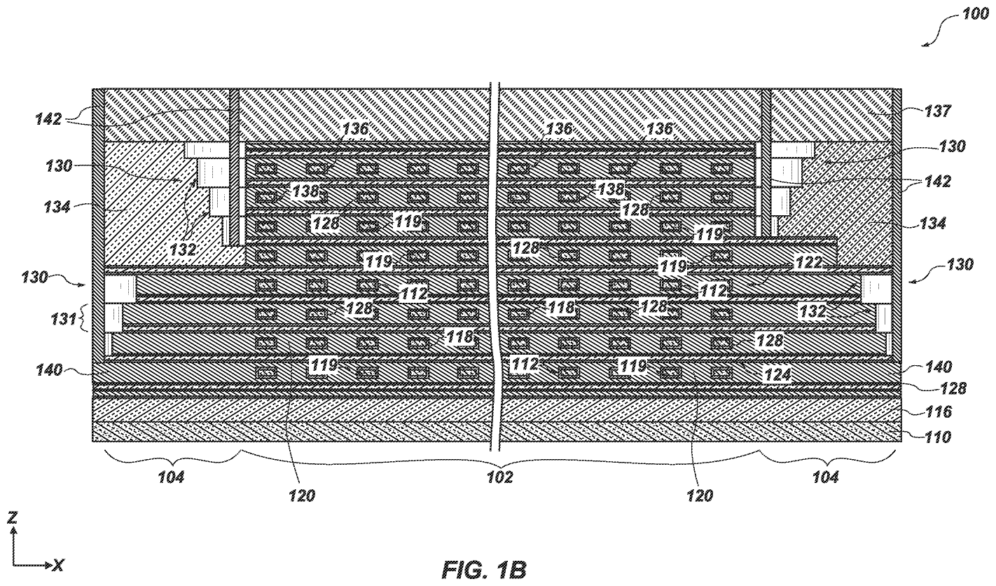

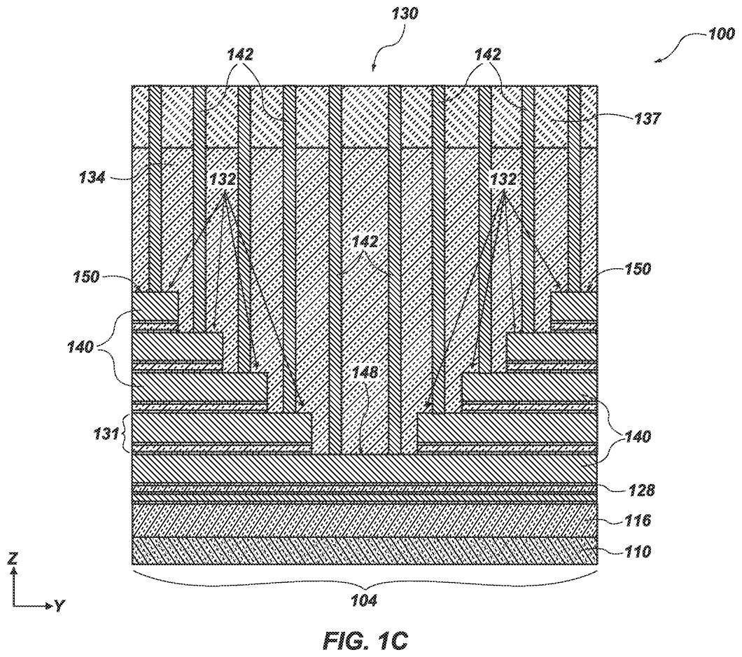

FIGS. 1A through 1C are a simplified, partial top-down view (FIG. 1A) and simplified, partial cross-sectional views (FIGS. 1B and 1C) of a microelectronic device structure 100 (e.g., a memory device, such as a 3D DRAM memory device), in accordance with embodiments of the disclosure. With the description provided below, it will be readily apparent to one of ordinary skill in the art that the methods and structures described herein with reference to FIGS. 1A through 1C may be used in various devices and electronic systems.

FIG. 1A is a simplified, partial top-down view of the microelectronic device structure 100; FIG. 1B is a simplified, partial cross-sectional view of the microelectronic device structure 100 taken through section line B-B of FIG. 1A; and FIG. 1C is a simplified, partial cross-sectional view of the microelectronic device structure 100 taken through section line C-C of FIG. 1A.

Referring to FIG. 1A, the microelectronic device structure 100 includes an array region 102 (also referred to herein as a “memory array region”), and one or more staircase regions 104 (also referred to herein as a “contact landing regions”) located horizontally adjacent to the array region 102. In some embodiments, a single staircase region 104 is horizontally adjacent to the array region 102 in a first horizontal direction (e.g., in the X-direction). In other embodiments, more than one (e.g., two) of the staircase regions 104 are horizontally adjacent to the array region 102 (e.g., on two opposing sides thereof) in the first horizontal direction.

The staircase regions 104 may include staircase structures 130 including conductive contact structures 142 coupled thereto. The conductive contact structures 142 may connect (e.g., electrically connect) one or more components of the microelectronic device structure 100 to circuitry of a second microelectronic device structure or to one or more additional components (e.g., sub word line drivers).

Conductive contact exit regions 106 may, optionally, horizontally neighbor (e.g., in the X-direction) the staircase regions 104. In some embodiments, the conductive contact exit regions 106 are located at horizontal ends (e.g., in the Y-direction) of the array region 102. The conductive contact exit regions 106 may include additional conductive contacts for electrically connecting one or more components (e.g., global conductive structures 127) of the microelectronic device structure 100 to additional circuitry external to the array region 102.

With reference to FIGS. 1A and 1B, within the array region 102, the microelectronic device structure 100 includes vertical (e.g., in the Z-direction) stacks of memory cells 108 over a base structure 110. Each vertical stack of memory cells 108 comprises a vertical stack of access devices 112 and a vertical stack of storage devices 114, the storage devices 114 of the vertical stack of storage devices 114 coupled to the access devices 112 of the vertical stack of access devices 112. The vertical stacks of storage devices 114 vertically overlie (e.g., in the Z-direction) the base structure 110. The vertical stack of access devices 112 may horizontally neighbor (e.g., in the Y-direction) the vertical stack of storage devices 114.

The vertical stacks of memory cells 108 may individually include vertically spaced (e.g., in the Z-direction) levels of memory cells 108, each memory cell 108 individually comprising a storage device 114 horizontally neighboring an access device 112. Although FIG. 1A illustrates a particular quantity of the vertical stacks of memory cells 108, the disclosure is not so limited, and the array region 102 may include fewer or, alternatively, more of the vertical stacks of memory cells 108 than those illustrated.

The base structure 110 may include a conventional silicon substrate (e.g., a conventional silicon wafer), or another bulk substrate comprising a semiconductive material. As used herein, the term “bulk substrate” means and includes not only silicon substrates, but also silicon-on-insulator (all) substrates, such as silicon-on-sapphire (SOS) substrates and silicon-on-glass (SOG) substrates, epitaxial layers of silicon on a base semiconductive foundation, and other substrates formed of and including one or more semiconductive materials (e.g., one or more of a silicon material, such monocrystalline silicon or polycrystalline silicon; silicon-germanium; germanium; gallium arsenide; a gallium nitride; and indium phosphide). In some embodiments, the base structure 110 comprises a silicon wafer.

In some embodiments, the base structure 110 includes different materials, structures, devices, and/or regions formed therein and/or thereon. In some embodiments, the base structure 110 includes complementary metal-oxide-semiconductor (CMOS) circuitry and devices configured for effectuating operation of the vertical stacks of memory cells 108 of the microelectronic device structure 100.

With reference to FIG. 1B, the base structure 110 may be electrically isolated from the vertical stacks of memory cells 108 by a first insulative material 116 vertically intervening (e.g., in the Z-direction) between the base structure 110 and the vertical stacks of memory cells 108. The first insulative material 116 may be formed of and include insulative material such as, for example, one or more of an oxide material (e.g., silicon dioxide (SiO₂), phosphosilicate glass, borosilicate glass, borophosphosilicate glass, fluorosilicate glass, titanium dioxide (TiO₂), hafnium oxide (HfO₂), zirconium dioxide (ZrO₂), hafnium dioxide (HfO₂), tantalum oxide (TaO₂), magnesium oxide (MgO), aluminum oxide (Al₂O₃), or a combination thereof), and amorphous carbon. In some embodiments, the first insulative material 116 comprises SiO₂.

Each access device 112 of the vertical stack of access devices 112 individually includes a channel region 118 comprising a channel material 119 in electrical communication with at least a portion of the horizontally neighboring (e.g., in the Y-direction) the storage device 114 (e.g., a first electrode 144 of the horizontally neighboring storage device 114).

The channel material 119 may be formed of and include, for example, a semiconductive material (e.g., silicon). In some embodiments, the channel material 119 comprises silicon, such as epitaxially grown silicon. In some embodiments, the channel material 119 comprises a semiconductive material (e.g., polysilicon) doped with at least one N-type dopant or at least one P-type dopant. In some embodiments, at least some portions of the channel material 119 are doped with one of at least one N-type dopant (e.g., one or more of arsenic ions, phosphorous ions, and antimony ions) and at least one P-type dopant (e.g., one or more of boron ions, aluminum ions, and gallium ions) and at least other portions of the channel material 119 are doped with the other of the at least one N-type dopant and the at least one P-type dopant to form the channel region 118.

Each of the access devices 112 may individually be coupled (e.g., electrically connected) to one or more first conductive structures 120 (also referred to herein as “first conductive lines,” “first access lines,” or “first word lines”). The first conductive structures 120 vertically overlying (e.g., in the Z-direction) the base structure 110 and within horizontal boundaries (e.g., in the X-direction, in the Y-direction) of one another may form a vertical stack structure 122 of the first conductive structures 120. The vertical stack structure 122 comprises levels of the first conductive structures 120 vertically spaced (e.g., in the Z-direction) from one another. The first conductive structures 120 of the vertical stack structure 122 within the array region 102 may individually be coupled to additional conductive structures of the vertical stack structure 122 within the staircase region 104, as described below.

The first conductive structures 120 may extend horizontally through (e.g., in the X-direction) the microelectronic device structure 100 (e.g., through the vertical stacks of memory cells 108) as conductive lines (e.g., word lines) and may each be configured to be coupled to a vertically neighboring (e.g., in the Z-direction) access device 112 (e.g., the channel region 118 of a neighboring access device 112). A first conductive structure 120 may be configured to be coupled to a vertically neighboring access device 112. With reference to FIG. 1B, the access devices 112 may individually be located vertically between (e.g., in the Z-direction) portions of a first conductive structure 120. In some embodiments, the access devices 112 are individually located vertically within (e.g., in the Z-direction) vertical boundaries of a first conductive structure 120. In other embodiments, the first conductive structures 120 are configured as digit lines (e.g., horizontal digit lines).

The first conductive structures 120 may individually be formed of and include conductive material, such as, for example, one or more of a metal (e.g., tungsten, titanium, nickel, platinum, rhodium, ruthenium, aluminum, copper, molybdenum, iridium, silver, gold), a metal alloy, a metal-containing material (e.g., metal nitrides, metal silicides, metal carbides, metal oxides), a material including at least one of titanium nitride (TiNₓ), tantalum nitride (TaNₓ), tungsten nitride (WNₓ), titanium aluminum nitride (TiAlₓN_{y}), iridium oxide (IrOₓ), ruthenium oxide (RuOₓ), alloys thereof, a conductively doped semiconductor material (e.g., conductively doped silicon, conductively doped germanium, conductively doped silicon germanium, etc.), polysilicon, or other materials exhibiting electrical conductivity. In some embodiments, the first conductive structures 120 individually comprise tungsten. In other embodiments, the first conductive structures 120 individually comprise TiN x.

The first conductive structures 120 may individually be configured to provide sufficient voltage to the channel region 118 directly vertically neighboring (e.g., in the Z-direction) the respective access device 112 to couple a storage device 114 horizontally neighboring (e.g., in the Y-direction) and associated with the access device 112 to, for example, a conductive pillar structure (e.g., a digit line) vertically extending (e.g., in the Z-direction) through or proximate the vertical stack of access devices 112 of the vertical stack of memory cells 108. Each first conductive structure 120 may individually comprise a gate structure configured to provide a sufficient voltage (e.g., a threshold switching voltage) to the channel region 118 vertically neighboring (e.g., in the Z-direction) the first conductive structure 120 to electrically connect a conductive routing structure coupled to the access device 112 including the channel region 118 to the horizontally neighboring (e.g., in the Y-direction) storage device 114.

The vertical stack structure 122 including the first conductive structures 120 may intersect the vertical stacks of memory cells 108 of the array region 102, such as the vertical stacks of the access devices 112 of the vertical stacks of memory cells 108. An individual first conductive structure 120 of the vertical stack structure 122 may intersect an individual level (e.g., a tier 131) of the memory cells 108 of the vertical stack of memory cells 108. An individual first conductive structure 120 may intersect and comprise a portion of a number of vertical stacks of access devices 112 (e.g., a gate of the access devices 112).

With reference to FIG. 1A, the first conductive structures 120 may individually extend through and intersect several vertical stacks of access devices 112 of the vertical stack of memory cells 108. In some embodiments, each of the first conductive structures 120 extends through horizontally neighboring (e.g., in the X-direction) vertical stacks of memory cells 108. In some embodiments, the first conductive structures 120 extending in a first horizontal direction (e.g., in the X-direction) are spaced from each other in a second horizontal direction (e.g., in the Y-direction) orthogonal to the first horizontal direction.

Although FIGS. 1A and 1B illustrate that the first conductive structures 120 of the vertical stack structure 122 individually intersect and form portions of a particular quantity of the vertical stacks of memory cells 108, the disclosure is not so limited. In other embodiments, the first conductive structures 120 of the vertical stack structure 122 individually intersect and form portions of fewer or, alternatively, more of the vertical stacks of memory cells 108 than those illustrated.

As shown in FIG. 1B, in some embodiments, vertically neighboring (e.g., in the Z-direction) first conductive structures 120 between vertically neighboring (e.g., in the Z-direction) access devices 112 are spaced from each other by a second insulative material 124. The second insulative material 124 may be formed of and include an insulative material that is different than, and that has an etch selectivity with respect to, the channel material 119. In some embodiments, the second insulative material 124 is formed of and includes one or more of the materials described above with reference to the first insulative material 116. In some embodiments, the second insulative material 124 is formed of and includes an oxide material (e.g., SiO₂).

With returned reference to FIG. 1A, the microelectronic device structure 100 may include conductive pillar structures 126 vertically extending (e.g., in the Z-direction) through the microelectronic device structure 100. The conductive pillar structures 126 may also be referred to herein as “digit lines,” “digit line pillar structures,” or “vertical digit lines.” The conductive pillar structures 126 may be coupled to the access devices 112 to facilitate operation of the memory cells 108 of a vertical stack of memory cells 108. Each conductive pillar structure 126 vertically extends directly horizontally neighboring (e.g., in the Y-direction) and in contact with access devices 112 of a vertical stack of memory cells 108. In some embodiments, each vertical stack of memory cells 108 includes one of the conductive pillar structures 126 vertically extending (e.g., in the Z-direction) and horizontally neighboring (e.g., in the Y-direction) the vertical stack of memory cells 108 (e.g., proximate the vertical stack of access devices 112 of the memory cells 108). In some embodiments, the conductive pillar structures 126 are in electrical communication with the base structure 110 (FIG. 1B). In other embodiments, the conductive pillar structures 126 are configured as access lines (e.g., vertical access lines, vertical word lines) coupled to the vertical stacks of memory cells 108.

The conductive pillar structures 126 may individually be formed of and include conductive material, such as one or more of a metal (e.g., one or more of tungsten, titanium, nickel, platinum, rhodium, ruthenium, aluminum, copper, molybdenum, iridium, silver, gold), a metal alloy, a metal-containing material (e.g., metal nitrides, metal silicides, metal carbides, metal oxides), a material including at least one of titanium nitride (TiNₓ), tantalum nitride (TaNₓ), tungsten nitride (WNₓ), titanium aluminum nitride (TiAlₓN_{y}), iridium oxide (IrOₓ), ruthenium oxide (RuOₓ), alloys thereof, a conductively doped semiconductor material (e.g., conductively doped silicon, conductively doped germanium, conductively doped silicon germanium, etc.), or other materials exhibiting electrical conductivity. In some embodiments, the conductive pillar structures 126 comprise tungsten.

The microelectronic device structure 100 may include global conductive structures 127 (e.g., global conductive lines, global digit lines), illustrated in broken lines, formed vertically over (e.g., in the Z-direction) and in electrical communication with the conductive pillar structures 126. The global conductive structures 127 may or may not vertically overlie (e.g., in the Z-direction) the vertical stacks of memory cells 108. In some embodiments, the global conductive structures 127 horizontally extend (e.g., in the Y-direction) through the microelectronic device structure 100. For example, the global conductive structures 127 may be coupled to the conductive pillar structures 126 and to additional conductive contacts within the conductive contact exit regions 106. In some such embodiments, the global conductive structures 127 horizontally extend substantially continuously through the array region 102 and terminate in each of the conductive contact exit regions 106. First longitudinal ends of the global conductive structures 127 may terminate in one of the conductive contact exit regions 106 and second longitudinal ends of the global conductive structures 127 may terminate in the other of the conductive contact exit regions 106, although other configurations may be contemplated.

For convenience, only the global conductive structures 127 proximal to the conductive contact exit regions 106 are illustrated as being coupled to the conductive pillar structures 126 in FIG. 1A, although it is understood that additional global conductive structures 127 may be coupled to remaining portions of the conductive pillar structures 126. In some embodiments, each of the global conductive structures 127 is coupled to more than one (e.g., two, three, four, six, eight) of the conductive pillar structures 126. The global conductive structures 127 may be formed of and include conductive material, such as one or more of the materials described above with reference to the conductive pillar structures 126.

With reference to FIG. 1B, each of the access devices 112 may be surrounded by dielectric material 128, which may also be referred to herein as a “gate dielectric material.” The channel region 118 is separated from the first conductive structures 120 by the dielectric material 128. The first conductive structures 120 are separated from the access devices 112 by the dielectric material 128. In some embodiments, the portion of the first conductive structure 120 directly vertically neighboring (e.g., in the Z-direction) and located within horizontal boundaries (e.g., in the X-direction, in the Y-direction) of the dielectric material 128 may be referred to as a “gate electrode.”

In some embodiments, each of the access devices 112 is substantially surrounded by the dielectric material 128 that is, in turn, substantially surrounded by the first conductive structure 120. In some such embodiments, the access devices 112 individually comprise so-called “gate all around” access devices (e.g., gate all around transistors) since each of the access devices 112 is individually substantially surrounded by one of the first conductive structures 120.

The dielectric material 128 may be formed of and include insulative material. By way of non-limiting example, the dielectric material 128 may comprise one or more of phosphosilicate glass, borosilicate glass, borophosphosilicate glass (BPSG), fluorosilicate glass, SiO₂, TiO₂, ZrO₂, HfO₂, TaO₂, MgO, Al₂O₃, niobium oxide, molybdenum oxide, strontium oxide, barium oxide, yttrium oxide, a nitride material, (e.g., silicon nitride (Si₃N₄)), an oxynitride (e.g., silicon oxynitride, another gate dielectric material, a dielectric carbon nitride material (e.g., silicon carbon nitride (SiCₓN_{y})), or a dielectric carboxynitride material (e.g., silicon carboxynitride (SiOₓC_{y}N_{z})).

In some embodiments, the dielectric material 128 is also be located on surfaces of the first conductive structures 120 and between the first conductive structures 120 and the second insulative material 124. Portions of the dielectric material 128 on surfaces of the second insulative material 124 may not be referred to as a “gate dielectric” material.

As shown in FIG. 1A, the storage devices 114 are in electrical communication with a conductive plate structure 129. The conductive plate structure 129 may be formed of and include conductive material, such as one or more of the materials of an electrode (e.g., a second electrode 146) of one or more of the storage devices 114. In some embodiments, the conductive plate structure 129 comprises substantially the same material composition as an electrode of one or more of storage devices 114. In other embodiments, the conductive plate structure 129 comprises a different material composition than any of the electrodes of the storage devices 114. The conductive plate structures 129 may be referred to herein as “conductive plates” or “ground structures.” The conductive plate structures 129 horizontally extend (e.g., in the X-direction) as conductive plates. In some embodiments, the conductive plate structures 129 horizontally extend in substantially the same direction and are substantially parallel to the first conductive structures 120. The conductive plate structures 129 may be horizontally between (e.g., in the Y-direction) vertical stacks of memory cells 108, such as between vertical stacks of storage devices 114.

As shown in FIG. 1B, vertically uppermost (e.g., in the Z-direction) access devices 112 may, optionally, form a multiplexer 136. In some embodiments, the global conductive structures 127 are individually in electrical communication with a multiplexer 136 to selectively couple the global conductive structure 127 to one of the conductive pillar structures 126 through the multiplexer 136. In some embodiments, the multiplexers 136 are individually in electrical communication with one of the first conductive structures 120 horizontally neighboring (e.g., in the Y-direction) the multiplexer 136.

The access devices 112 vertically neighboring (e.g., vertically below) the multiplexers 136 may, optionally, individually comprise a transistor 138 configured to electrically couple a horizontally neighboring (e.g., in the X-direction) conductive pillar structure 126 to the conductive plate structure 129 through an additional conductive structure (e.g., a semiconductive material). The transistor 138 may comprise a so-called “bleeder” transistor or a “leaker” transistor configured to provide a bias voltage to the conductive pillar structures 126 to which it is coupled (e.g., the horizontally neighboring (e.g., in the Y-direction) conductive pillar structures 126). In some embodiments, the first conductive structure 120 coupled to the transistors 138 are in electrical communication with a voltage, such as a drain voltage V_{dd} or a voltage source supply Vₛₛ. In use and operation, the transistors 138 are configured to provide a negative voltage to the conductive pillar structures 126 of unselected (e.g., inactive) vertical stacks of memory cells 108. The transistors 138 are configured to electrically connect unselected conductive pillar structures 126 with their respective conductive plate structures 129 (e.g., ground structures, cell plates), which may be coupled to a negative voltage. In some embodiments, each vertical stack of memory cells 108 includes at least one (e.g., one) of the multiplexers 136 and at least one (e.g., one) of the transistors 138.

While the vertically uppermost access devices 112 are illustrated as being multiplexers 136 and the access devices 112 vertically neighboring the multiplexers 136 are illustrated as the transistors 138 for clarity and ease of understanding of the drawings and related description, other configurations may be contemplated. For example, vertically lowermost access devices 112 (e.g., proximal the base structure 110) may, alternatively, be formed as the multiplexers 136 and the access devices 112 vertically neighboring the multiplexers 136 may comprise the transistors 138.

As shown in FIG. 1A, in combination with FIG. 1B, the vertical stacks of storage devices 114 vertically overlie (e.g., in the Z-direction) the base structure 110. Each of the storage devices 114 individually comprises the first electrode 144 (e.g., an outer electrode), the second electrode 146 (e.g., an inner electrode), and dielectric material therebetween. For convenience, only three (3) of the storage devices 114 are illustrated as including the first electrode 144 and the second electrode 146 in FIG. 1A, although it is understood that each of the storage devices 114 may include the first electrode 144 and the second electrode 146. In some such embodiments, the storage devices 114 individually comprise capacitors. However, the disclosure is not so limited and in other embodiments, the storage devices 114 each individually comprise other structures, such as, for example, phase change memory (PCM), resistance random-access memory (RRAM), conductive-bridging random-access memory (conductive bridging RAM), or another structure for storing a logic state.

At least a portion of each storage device 114 is in electrical communication with a horizontally neighboring (e.g., in the X-direction) access device 112. In some embodiments, the first electrode 144 of each storage device 114 is in electrical communication with (and directly contacts) a horizontally neighboring access device 112. The first electrode 144 and the second electrode 146 may individually be formed of and include conductive material. In some embodiments, one or more of the first electrode 144 and the second electrode 146 comprises titanium nitride. In some embodiments, the second electrode 146 comprises substantially the same material composition as the first electrode 144.

The second electrode 146 may be in electrical communication with one of the conductive plate structures 129 of a vertical stack of memory cells 108. In some embodiments, the second electrodes 146 are substantially integral with the conductive plate structures 129. In some embodiments, the second electrodes 146 of horizontally neighboring (e.g., in the X-direction) vertical stacks of storage devices 114 are in electrical communication with the same conductive plate structure 129.

With continued reference to FIGS. 1A and 1B, the first conductive structures 120 of the vertical stack structure 122 within the array region 102 may be coupled to second conductive structures 140 (also referred to herein as “second conductive lines,” “second access lines,” or “second word lines”) within the staircase region 104. The second conductive structures 140 of the vertical stack structure 122 may vertically overlie (e.g., in the Z-direction) the base structure 110 and be located within horizontal boundaries (e.g., in the X-direction, in the Y-direction) of the staircase region 104. Each of the first conductive structures 120 may be individually coupled to one of the second conductive structures 140.

The second conductive structures 140 may physically contact the first conductive structures 120 along vertical interfaces coinciding with a horizontal boundary between the staircase regions 104 and the array region 102. The first conductive structures 120 and the second conductive structures 140 at each vertical level individually exhibit substantially the same vertical position (e.g., in the Z-direction) as one another. Further, upper surfaces of the first conductive structures 120 and the second conductive structures 140 at each vertical level may be substantially coplanar with one another, and lower surfaces of the first conductive structures 120 and the second conductive structures 140 at each vertical level may be substantially coplanar with one another. Vertically spaced (e.g., in the Z-direction) levels of conductive structures of the vertical stack structure 122 may include a first portion (e.g., a first conductive structure 120) within the array region 102 and a second portion (e.g., a second conductive structure 140) within the staircase regions 104. For clarity and ease of understanding the drawings and associated description, the second conductive structures 140 are differentiated from the first conductive structures 120 by their locations (e.g., within the staircase regions 104 and the array region 102, respectively). In other embodiments, the second conductive structures 140 are configured as digit lines (e.g., horizontal digit lines), such as when the first conductive structures 120 are configured as digit lines and the conductive pillar structures 126 are configured as access lines.

The second conductive structures 140 may be formed of and include conductive material, such as one or more of the materials described above with reference to the first conductive structures 120. The first conductive structures 120 and the second conductive structures 140 may include substantially the same material composition with no readily discernable physical interface therebetween. Further, the second conductive structures 140 may be substantially continuous with the first conductive structures 120 at each vertical level of the vertical stack structure 122 and may be formed during (e.g., substantially simultaneous with) formation of the first conductive structures 120. By forming the second conductive structures 140 during formation of the first conductive structures 120, manufacturing costs may be reduced. Alternatively, the second conductive structures 140 and the first conductive structures 120 may include a material composition that differs from one another, such that a material composition of the second conductive structures 140 differs from a material composition of the first conductive structures 120.

Since more than one (e.g., two) of the staircase regions 104 may be horizontally adjacent to the array region 102 (e.g., on two opposing sides thereof) in the first horizontal direction, the second conductive structures 140 may be horizontally adjacent to the first conductive structures 120 on the two opposing sides thereof. In other embodiments, the second conductive structures 140 may be horizontally adjacent to the first conductive structures 120 on only one side thereof, such as when a single staircase region 104 is horizontally adjacent to the array region 102 in the first horizontal direction.

The second conductive structures 140 may exhibit different configurations (e.g., different size(s) and/or different shape(s)) than the first conductive structures 120. For example, the first conductive structures 120 may individually exhibit a rectangular prism shape having a substantially rectangular horizontal cross-sectional (e.g., substantially linear) shape extending in the X-direction. Portions of the second conductive structures 140 proximal to the horizontal boundary of the array region 102 (e.g., proximal to the vertical interface with the first conductive structures 120) may also exhibit a rectangular prism shape having a substantially rectangular horizontal cross-sectional shape substantially linearly extending in the X-direction. Additional portions of the second conductive structures 140 distal from the horizontal boundary of the array region 102 (e.g., distal from the first conductive structures 120) may individually exhibit an at least partially non-rectangular horizontal cross-sectional shape extending in non-linear horizontal paths. For example, the second conductive structures 140 may individually include first portions extending in the first horizontal direction (e.g., the X-direction) and second portions horizontally adjacent to the first portions and extending in the second horizontal direction (e.g., the Y-direction), as described in further detail below.

The second conductive structures 140 may horizontally (e.g., in the X-direction, in the Y-direction) terminate at the staircase structures 130 located at horizontally terminal portions of the vertical stack structure 122. The staircase structures 130 may be located within the staircase regions 104; and may individually exhibit one or more closed curve horizontal cross-sectional shape(s). The staircase structures 130 of the microelectronic device structure 100, as shown in FIG. 1A, may be defined by at least partially non-linear (e.g., curved, arcuate) horizontal boundaries (e.g., horizontal ends, horizontal edges) of the vertical stack structure 122. For example, the staircase structures 130 may exhibit at least partially curved horizontal cross-sectional shapes (e.g., closed curve horizontal cross-sectional shapes) at different vertical elevations thereof, and may be separated from one another in the X-direction and in the Y-direction. In some embodiments, the staircase structures 130 individually exhibit partially curved horizontal cross-sectional shapes (e.g., in an XY-plane) individually including a combination of linear horizontally extending portions and non-linear (e.g., arcuate) horizontally extending portions at different vertical elevations (e.g., in the Z-direction) thereof.

In some embodiments, the staircase structures 130 of the vertical stack structure 122 horizontally neighbor (e.g., in the X-direction) the array region 102. In some such embodiments, the vertical stack structure 122 includes two of the staircase regions 104 including the staircase structures 130. For example, the vertical stack structure 122 may include some of the staircase structures 130 within a first staircase region 104a at a first horizontal end (e.g., in the X-direction) of the microelectronic device structure 100 and may include some others of the staircase structures 130 within a second staircase region 104b at a second horizontal end (e.g., in the X-direction) of the microelectronic device structure 100 opposite the first horizontal end. Accordingly, each vertical stack structure 122 may individually include a staircase region 104 (e.g., the first staircase region 104a) including some of the staircase structures 130 at a first horizontal end of the vertical stack structure 122 and an additional staircase region 104 (e.g., the second staircase region 104b) including some others of the staircase structures 130 at a second, opposite horizontal end of the vertical stack structure 122. Although FIG. 1A illustrates one staircase region 104 including the staircase structures 130 at each horizontal end (e.g., in the X-direction) of the vertical stack structure 122, the disclosure is not so limited. In other embodiments, the vertical stack structure 122 includes one staircase region 104 including the staircase structures 130 for every vertical stack structure 122 (e.g., staircase structures 130 at only one horizontal (e.g., in the X-direction) end of each vertical stack structure 122).

With continued reference to FIG. 1A, within an individual staircase region 104, the staircase structures 130 thereof may be arranged such that portions of at least some staircase structures 130 horizontally neighboring one another horizontally overlap one another in multiple horizontal directions (e.g., the X-direction and the Y-direction). The staircase structures 130 of the staircase regions 104 may, for example, be arranged in a weave pattern (e.g., a hexagonal pattern, such as hexagonal close-packed pattern). In some embodiments, the staircase structures 130 are arranged relative to one another in hexagonal pattern exhibiting a repeating horizontal arrangement of seven (7) staircase structures 130, wherein one (1) of the seven (7) staircase structures 130 is substantially horizontally centered between six (6) other of the seven (7) staircase structures 130. The hexagonal pattern may exhibit three (3) different axes of symmetry in the same lateral plane (e.g., the XY plane) about a center of the horizontally centered staircase structures 130 of the seven (7) staircase structures 130. Different axes of symmetry directly radially adjacent to one another may be radially separated from one another by an angle θ of about 60 degrees.

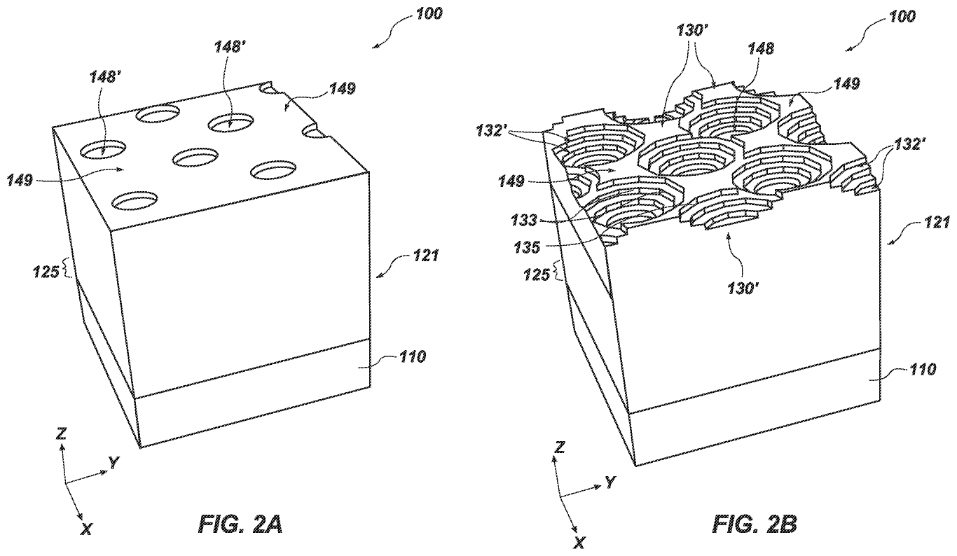

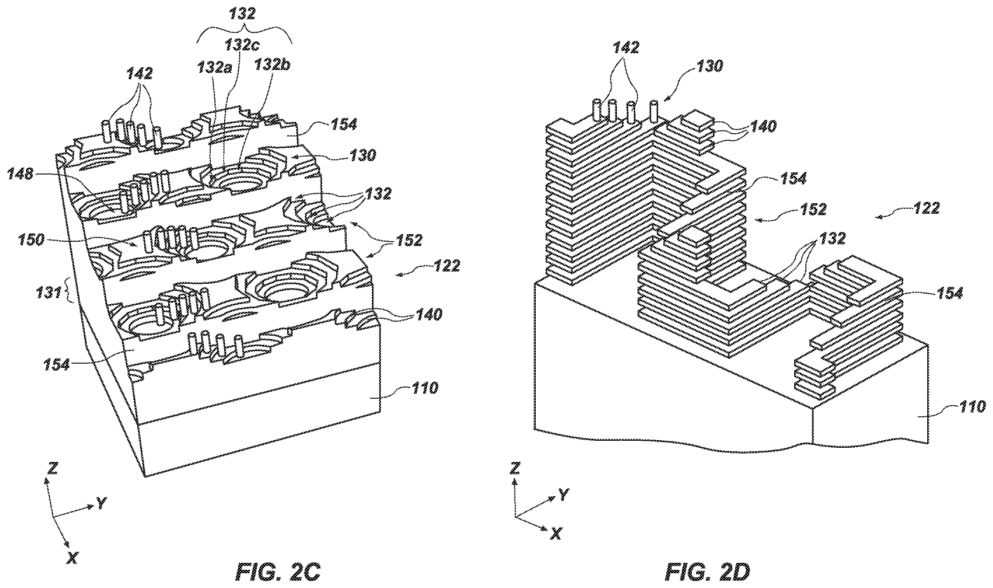

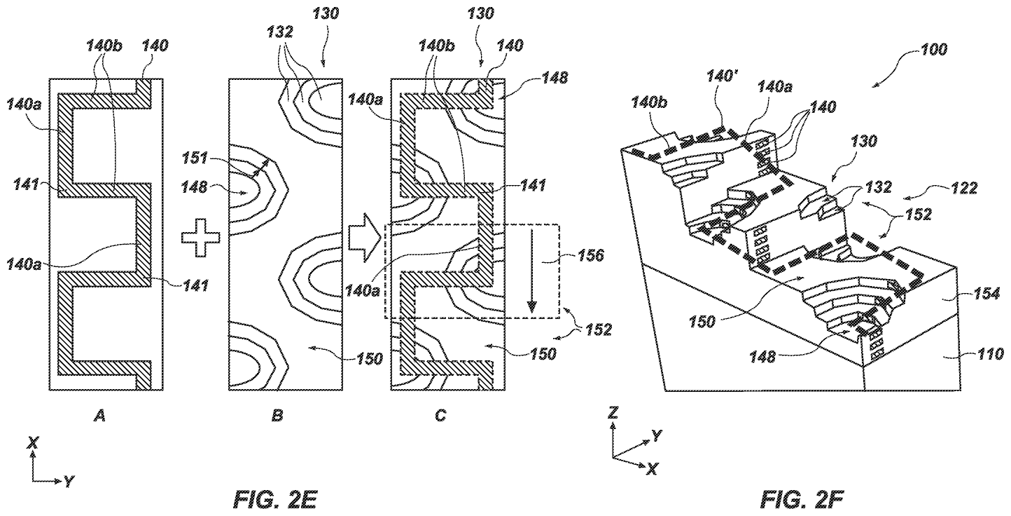

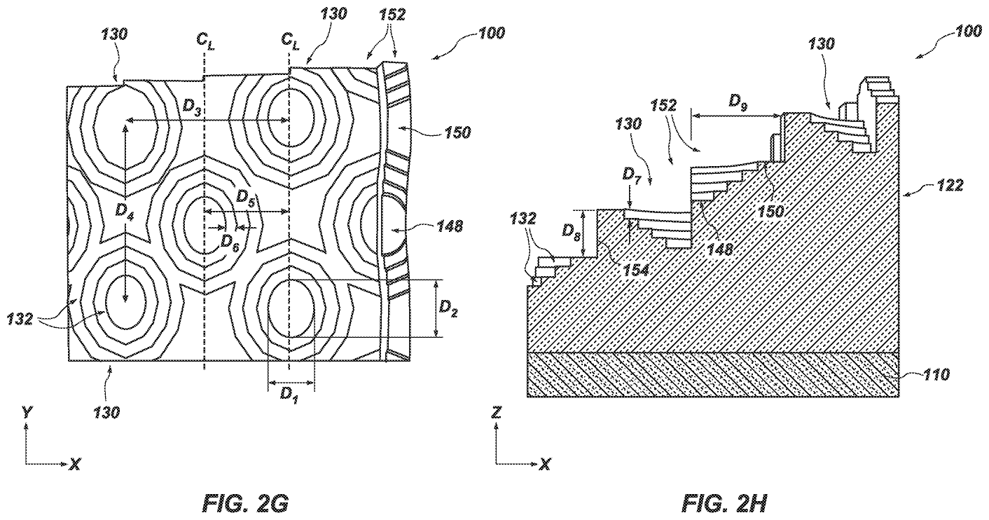

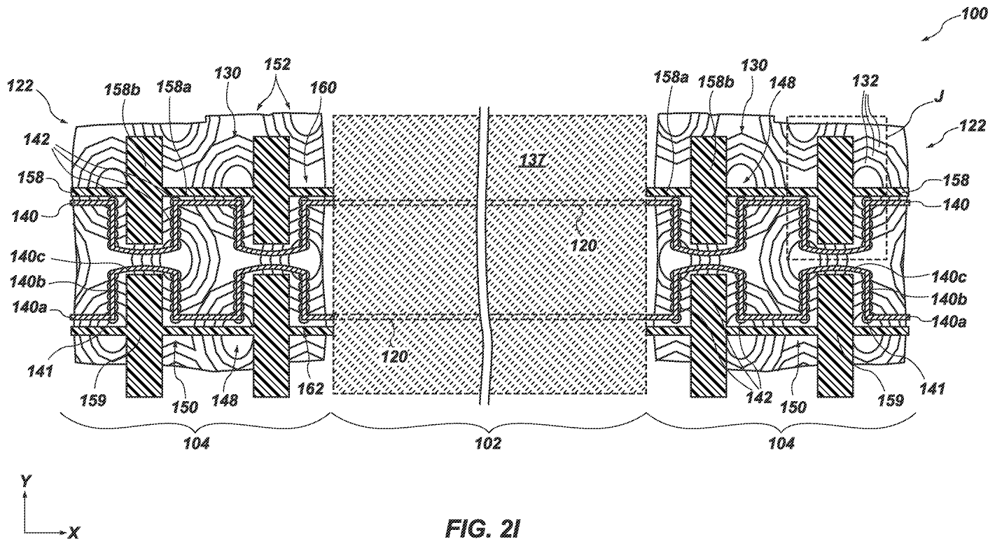

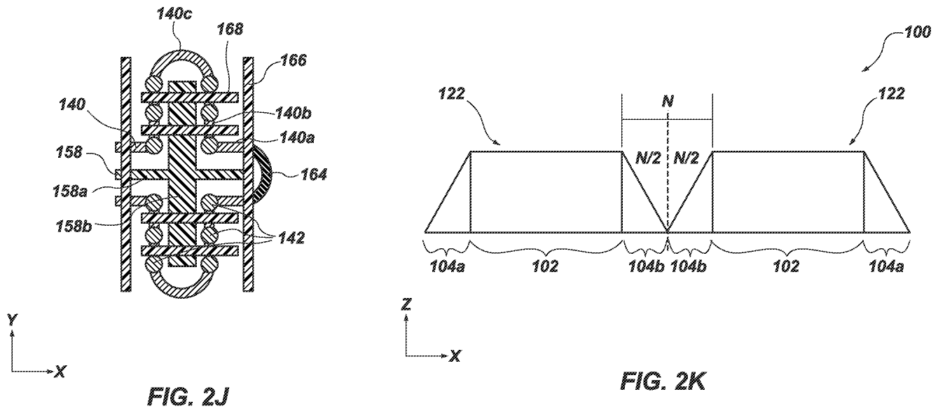

In some embodiments, the staircase structures 130 individually exhibit a maximum lateral dimension (e.g., a maximum length) in the second horizontal direction (e.g., the Y-direction) that is larger than another maximum lateral dimension (e.g., a maximum width) in the first horizontal direction (e.g., the X-direction). The staircase structures 130 may individually exhibit partially curved horizontal cross sectional shapes (e.g., closed curve horizontal cross sectional shapes) derived from closed curve horizontal cross-sectional shapes (e.g., elliptical horizontal cross-sectional shapes) of initial staircase structures employed to form the staircase structures 130, as described in further detail below with reference to FIGS. 2A through 2K. In addition, different vertical elevations (e.g., in the Z-direction) within an individual staircase structure 130 may exhibit substantially the same horizontal cross-sectional shape (e.g., substantially the same closed curve horizontal cross-sectional shape, such as substantially the same elliptical horizontal cross-sectional shape) as one another, or one or more different vertical elevations within an individual staircase structure 130 may exhibit different horizontal cross-sectional shapes (e.g., different closed curve horizontal cross-sectional shapes; at least one closed curve horizontal cross-sectional shape and at least one open curve horizontal cross-sectional shape) than one another.

Each of the staircase structures 130 may exhibit substantially the same geometric configuration (e.g., substantially the same dimensions, substantially the same shape) as each other of the staircase structures 130, or one or more of the staircase structures 130 may exhibit a different geometric configuration (e.g., one or more different dimensions, a different shape) than one or more of the staircase structures 130. In addition, horizontally neighboring staircase structures 130 may all be horizontally separated from one another by substantially the same distance, or two or more horizontally neighboring staircase structures 130 may be horizontally separated from one another by a different distance than a distance between two or more other horizontally neighboring staircase structures 130. In some embodiments, the staircase structures 130 are substantially uniformly (e.g., non-variably, equally, consistently) sized, shaped, and spaced relative to one another. In additional embodiments, at least some of the staircase structures 130 has one or more of a different size (e.g., a different overall horizontal area), a different shape, and different spacing than at least one other of the staircase structures 130.

In addition, each of the staircase regions 104 may exhibit substantially the same geometric configuration (e.g., substantially the same dimensions, substantially the same shape) as each other of the staircase regions 104, or one or more of the staircase regions 104 may exhibit a different geometric configuration (e.g., one or more different dimensions, a different shape) than one or more of the staircase regions 104. In some embodiments, each of the staircase regions 104 has substantially the same horizontal area as each other of the staircase regions 104. In additional embodiments, at least one of the staircase regions 104 has a different horizontal area (e.g., a smaller horizontal area, a larger horizontal area) than at least one other of the staircase regions 104.

With collective reference to FIG. 1A and FIG. 1C, vertically higher (e.g., in the Z-direction) second conductive structures 140 may have a smaller horizontal dimension (e.g., in the Y-direction) than vertically lower second conductive structures 140, such that horizontal edges of the second conductive structures 140 partially define steps 132 of the staircase structures 130. Vertically higher second conductive structures 140 may have a relatively smaller horizontal dimensions (e.g., in the X-direction) than the vertically lower second conductive structures 140. In some embodiments, the memory cells 108 of the vertical stack of memory cells 108 that are vertically higher (e.g., in the Z-direction) than other memory cells 108 are intersected by the first conductive structures 120, which, in turn, are horizontally adjacent to the second conductive structures 140 having relatively smaller horizontal dimensions (e.g., in the X-direction, in the Y-direction) than the second conductive structures 140 associated with vertically lower memory cells 108 of the vertical stacks of memory cells 108.

Relatively vertically higher second conductive structures 140 may also have relatively smaller horizontal dimensions than relatively vertically lower second conductive structures 140 in additional horizontal directions angularly offset from each of the X-direction and the Y-direction. The steps 132 of individual vertical levels include first portions extending in the first horizontal direction (e.g., the X-direction), second portions extending in the second horizontal direction (e.g., the Y-direction), and third portions between the first portions and the second portions and extending at an acute angle relative to the first horizontal direction and the second horizontal direction. In some embodiments, at least some of the steps 132 of individual vertical levels include individually angled linear portions horizontally adjacent to one another to define a relatively larger, closed curve horizontal cross-sectional shape of an individual step 132 of the staircase structure 130. In other embodiments, at least some of steps 132 of the individual vertical levels individually include at least one non-linear (e.g., substantially arcuate) portion defining a section of a closed curve horizontal cross-sectional shape of an individual step 132 the staircase structure 130. In further embodiments, at least two horizontal portions (e.g., two halves) of an individual staircase structure 130 are vertically offset from one another, such that a group of steps 132 within a horizontal area of one of the at least two horizontal portions vertically underlies an additional group of steps 132 within a horizontal area of an additional one of the at least two horizontal portions. From a top-down view, the staircase structure 130 may exhibit a closed curve horizontal shape, but the at least two horizontal portions that are vertically offset from one another may individually exhibit a different at least partially curved horizontal cross sectional shape (e.g., a different closed curve horizontal cross-sectional shape, an open curve horizontal cross-sectional shape).

Each staircase structure 130 may exhibit both a positive slope and a negative slope in each of the X-direction and the Y-direction. In some such embodiments, each staircase structure 130 may exhibit both a positive slope and a negative slope in additional direction (e.g., at acute angles to each of the X-direction and the Y-direction), such as when the staircase structures 130 exhibit an elliptical (e.g., circular) cross-sectional shape. In some embodiments, a phantom line extending from a top of a half of an individual staircase structure 130 to a bottom of the staircase structure 130 may have a positive slope on a first side thereof, and another phantom line extending from a top of the other half of the staircase structure 130 to the bottom of the staircase structure 130 may have a negative slope on a second, opposing side thereof. In some embodiments, for an individual vertical cross-section of an individual staircase structure 130, the positive slope and the negative slope of the staircase structure 130 have substantially the same magnitude as one another, corresponding to the change in vertical dimension (e.g., in the Z-direction) divided by the change in horizontal dimension (e.g., in the X-direction, in the Y-direction) of the staircase structure 130.

In some embodiments, the staircase structures 130 individually form a stadium structure having the steps 132 partially defined by edges (e.g., horizontal ends) of the second conductive structures 140 of the vertical stack structure 122. In some such embodiments, multiple (e.g., more than one) of the staircase structures 130 may be formed to be positioned at substantially the same elevations (e.g., vertical locations) as one another within the vertical stack structure 122. During formation of the steps 132 of the staircase structure 130, an initial staircase structure (e.g., configured substantially similar to the staircase structure 130) may be formed at an upper vertical position within the vertical stack structure 122 within horizontal boundaries of the staircase regions 104. The microelectronic device structure 100 may then be subjected to one or more additional material removal processes (e.g., one or more chopping processes) to increase the depth(s) (e.g., in the Z-direction) of the initial staircase structures relative to an upper surface of the vertical stack structure 122 and form the staircase structures 130, as described in further detail below.

One or more (e.g., two) of the second conductive structures 140 may be associated with one of the staircase structures 130. For example, one staircase structure 130 may be operatively associated with two of the second conductive structures 140. Further, each of the second conductive structures 140 may be associated with multiple (e.g., two or more) of the staircase structures 130. The second conductive structures 140 may individually horizontally extend in a multi-directional path (e.g., a non-linear horizontal path) to be associated with more than one of the staircase structures 130. For example, the second conductive structures 140 may individually include first portions extending in the first horizontal direction, and second portions horizontally adjacent to the first portions and extending in the second horizontal direction. As shown in FIG. 1A, for an individual staircase structure 130, the first portions of the second conductive structures 140 (e.g., portions extending in the X-direction) operatively associated with the staircase structure 130 partially define first portions of the steps 132 of the staircase structure 130, and the second portions of the second conductive structures 140 (e.g., portions extending in the Y-direction) operatively associated with the staircase structure 130 partially define second portions of the steps 132 of the staircase structure 130.

As shown in FIG. 1C, individual staircase structures 130 include a central portion 148 (e.g., a lowermost step 132 thereof) partially defined by a vertically lowermost second conductive structure 140 and a bridge 150 (e.g., an uppermost step 132 thereof) partially defined by a vertically uppermost second conductive structure 140. In some embodiments, the bridges 150 of neighboring staircase structures 130 physically contact (e.g., are coextensive with) one another, and the central portions 148 of the neighboring staircase structures 130 are spaced apart from one another. An individual vertically uppermost second conductive structure 140 may partially define the uppermost steps 132 of multiple (e.g., two, three, four) of neighboring staircase structures 130. Additional materials of the vertical stack structure 122 at the vertical level of the vertically uppermost second conductive structure 140 may be interposed between and may separate the staircase structures 130 from one another. Portions of the second conductive structures 140 partially defining the uppermost steps 132 of the staircase structures 130 comprise the bridge 150 (e.g., bridge regions) common to three or more of the staircase structures 130.

In some embodiments, portions of the staircase structures 130 of adjacent rows partially horizontally overlap one another in a horizontal direction (e.g., the Y-direction), and additional portions of the staircase structures 130 of adjacent columns partially horizontally overlap one another in another horizontal direction (e.g., the X-direction). Some of the steps 132 of the staircase structures 130 horizontally neighboring one another (e.g., in the X-direction, in the Y-direction) may horizontally overlap one another in one or more of the X-direction and the Y-direction. For example, a portion of a vertically highest (e.g., in the Z-direction) step 132 of a first staircase structure 130 may be substantially laterally aligned (e.g., in the X-direction) with a portion of a vertically highest step 132 of a second staircase structure 130, and another portion of the vertically highest step 132 of the first staircase structure 130 may be substantially laterally aligned (e.g., in the Y-direction) with a portion of a vertically highest step 132 of a third staircase structure 130. In some such embodiments, portions of additional steps 132 (e.g., second vertically highest steps 132, third vertically highest steps 132) horizontally overlap one another in the X-direction and in the Y-direction, in substantially the same manner as the vertically highest steps 132. Portions of additional steps 132 (e.g., the vertically lowest steps 132 (corresponding to the central portions 148), second vertically lowest steps 132) may not horizontally overlap one another in the X-direction and in the Y-direction.

A quantity of the steps 132 of an individual staircase structure 130 may correspond to a quantity of levels of memory cells 108 associated with the individual staircase structure 130. Although FIGS. 1A through 1C illustrate that the staircase structures 130 individually comprise a particular quantity (e.g., five (5)) of the steps 132, the disclosure is not so limited. In other embodiments, the staircase structures 130 each individually include a desired quantity of steps 132, such as within a range from about four (4) steps 132 to about eight (8) steps 132. However, the disclosure is not so limited, and additional configurations may be contemplated. In some such embodiments, each vertical stack of memory cells 108 of the microelectronic device structure 100 individually includes a corresponding quantity of memory cells 108 associated with a total quantity of the steps 132 of groups of the staircase structures 130. In other embodiments, the groups of the staircase structures 130 include a different number of the steps 132.

In some embodiments, the staircase structures 130 each individually include the same quantity of steps 132 as one another. In some embodiments, each step 132 of an individual staircase structure 130 has a tread that is vertically offset (e.g., in the Z-direction) from the tread of a vertically neighboring step 132 of the staircase structure 130 by one level (e.g., one tier 131) including the second conductive structures 140, the dielectric material 128, and the second insulative material 124. In some such embodiments, every second conductive structure 140 of the vertical stack structure 122 partially defines a tread of a step 132 at each horizontal end (e.g., in the X-direction) of the staircase structures 130 of the vertical stack structure 122.

In other embodiments, the treads of vertically neighboring (e.g., in the Z-direction) steps 132 of a staircase structure 130 on a first horizontal side (e.g., in the X-direction) of a vertical stack structure 122 are vertically offset (e.g., in the Z-direction) from one another by two levels (e.g., two tiers 131) individually including the second conductive structures 140, the dielectric material 128, and second insulative material 124. In some such embodiments, the treads of the steps 132 of an individual staircase structure 130 are formed by portions of every other second conductive structure 140 of the vertical stack structure 122; and the treads of the steps 132 of different, vertically neighboring staircase structures 130 at horizontally opposing ends (e.g., in the X-direction) of the same vertical stack structure 122 than one another may be partially defined by second conductive structures 140 that are vertically spaced (e.g., in the Z-direction) from one another by one level including the second conductive structures 140, the dielectric material 128, and the second insulative material 124.

As shown in FIGS. 1B and 1C, a third insulative material 134 may be formed to fill openings (e.g., valleys, spaces, gaps) vertically overlying and within horizontal areas of the staircase structures 130. In some embodiments, one or more insulative liner materials are interposed between the staircase structures 130 and the third insulative material 134. For clarity and ease of understanding the drawings and associated description, portions of the third insulative material 134 within horizontal areas of the staircase structures 130 are omitted from FIG. 1B. In some embodiments, the third insulative material 134 comprises SiOₓ (e.g., SiO₂). In additional embodiments, the third insulative material 134 comprises at least one different dielectric material, such as one or more of silicon oxycarbide (SiOₓC_{y}), silicon oxynitride (SiOₓN_{y}), hydrogenated silicon oxycarbide (SiCₓO_{y}H_{z}), or silicon oxycarbonitride (SiOₓC_{y}N_{z}).

A fourth insulative material 137 may be formed to vertically overlie (e.g., in the Z-direction) the vertical stack structure 122. The fourth insulative material 137, which may serve as a mask material, may also vertically overlie (e.g., in the Z-direction) the third insulative material 134 overlying the staircase structures 130. The fourth insulative material 137 may comprise one or more of the materials described above with reference to the first insulative material 116 (e.g., SiO₂).

With continued reference to FIGS. 1A through 1C, the conductive contact structures 142 may be formed to extend through the third insulative material 134 and the fourth insulative material 137. The conductive contact structures 142 may be in electrical communication with the second conductive structures 140 of the vertical stack structure 122 at the steps 132 of the staircase structure 130. For example, the conductive contact structures 142 may physically contact (e.g., land on) portions of upper surfaces of the second conductive structures 140 partially defining the treads of the steps 132. The conductive contact structures 142 may be formed at horizontal ends (e.g., lateral ends) of the second conductive structures 140. The conductive contact structures 142 may individually exhibit a substantially circular horizontal cross-sectional shape, as shown in the top-down view of FIG. 1A. However, the disclosure is not so limited. As a non-limiting example, in additional embodiments, the conductive contact structures 142 individually exhibit a substantially rectangular horizontal cross-sectional shape (e.g., a substantially square horizontal cross-sectional shape), or a different elongate horizontal cross-sectional shape (e.g., an oblong horizontal cross-sectional shape). For example, the conductive contact structures 142 may be elongated in a direction in which portions of the second conductive structures 140 extend (e.g., in the Y-direction) or, alternatively, in a direction in which portions of the steps 132 extend (e.g., in the X-direction).

In some embodiments, each step 132 of an individual staircase structure 130 may be in physical contact with one or more (e.g., two (2)) of the conductive contact structures 142. In other embodiments, only every other step 132 of an individual staircase structure 130 includes one or more conductive contact structures 142 in physical contact therewith. In some such embodiments, a group of the conductive contact structures 142 within a horizontal area of the first staircase region 104A physically contact different second conductive structures 140 of an individual vertical stack structure 122 than an additional group of the conductive contact structures 142 horizontal area of the second staircase region 104B. In some embodiments, a configuration of a group of the conductive contact structures 142 of the staircase structures 130 within the first staircase region 104a differs from a configuration of an additional group of the conductive contact structures 142 of the staircase structures 130 within the second staircase region 104b. For example, the staircase structures 130 of the vertical stack structure 122 within the first staircase region 104a may have conductive contact structures 142 landing on portions of even second conductive structures 140 partially defining the steps 132 of the staircase structures 130; and additional staircase structures 130 within the second staircase region 104b may have conductive contact structures 142 landing on portions of odd second conductive structures 140 partially defining the steps 132 of the additional staircase structures 130. The staircase structures 130 of the vertical stack structures 122 at the first horizontal end (e.g., in the X-direction) of the microelectronic device structure 100 may exhibit a first configuration, and the additional staircase structures 130 at the second, opposing horizontal end may exhibit a second configuration that differs from the first configuration, responsive to relative positions of the conductive contact structures 142 on the steps 132.

The conductive contact structures 142 may individually be formed of and include conductive material, such as one or more of the materials described above with reference to the conductive pillar structures 126. In some embodiments, the conductive contact structures 142 comprise substantially the same material composition as the conductive pillar structures 126. In other embodiments, the conductive contact structures 142 comprise a different material composition than the conductive pillar structures 126. In some embodiments, the conductive contact structures 142 comprise tungsten.

By forming the staircase structures 130 to individually exhibit at least partially curved horizontal cross-sectional shapes (e.g., closed curve horizontal cross-sectional shapes), the steps 132 of the staircase structures 130 may individually be formed to have a relatively greater horizontal cross-sectional area, without undesirably increasing the overall width (e.g., horizontal footprint) of the staircase regions 104 of the microelectronic device structure 100. A greater quantity of the conductive contact structures 142 may be formed within the staircase regions 104, which may permit a relatively greater quantity of the vertical stacks of memory cells 108 to be formed within the array region 102. Forming the microelectronic device structure 100 to include the staircase regions 104 including the staircase structures 130 of the disclosure may facilitate reducing a horizontal area of the microelectronic device structure 100 as compared to conventional microelectronic device structures. In addition, the second conductive structures 140 horizontally extending in multi-directional (e.g., non-linear) paths may facilitate efficient use of area of the staircase regions 104 such that an area allocated to the staircase structures 130 is reduced and reliability of the microelectronic device structure 100 is improved.

FIGS. 2A through 2K are simplified, partial perspective views (FIGS. 2A through 2D and 2F), simplified, partial top-down views (FIGS. 2E, 2G, 2I, and 2J), simplified, partial cross-sectional views (FIGS. 2H and 2K) illustrating a method of forming the microelectronic device structure 100 described above with reference to FIGS. 1A through 1C, in accordance with embodiments of the disclosure. FIG. 2J illustrates a simplified top-down view of a region J depicted in FIG. 2I by way of a dashed box. For clarity and ease of understanding the description, FIGS. 2A through 2K do not illustrate other components of the microelectronic device structure 100, such as the vertical stacks of memory cells 108 within the array region 102.

Referring to FIG. 2A, the microelectronic device structure 100 may be formed to include a preliminary stack structure 121 vertically overlying the base structure 110. The preliminary stack structure 121 may include a vertically alternating (e.g., in a Z-direction) sequence of insulative material and sacrificial material arranged in preliminary tiers 125. Each of the preliminary tiers 125 of the preliminary stack structure 121 may individually include the sacrificial material vertically neighboring (e.g., directly vertically adjacent) the insulative material. Portions of the sacrificial material of the preliminary tiers 125 of the preliminary stack structure 121 may subsequently be replaced with conductive material to form the second conductive structures 140 (FIGS. 1A through 1C), as described in further detail below with reference to FIG. 2C. In addition, the portions of insulative material of the preliminary tiers 125 of the preliminary stack structure 121 may form the second insulative material 124 (FIGS. 1B and 1C), as described in further detail below with reference to FIG. 2C. Furthermore, the preliminary stack structure 121 may include different horizontal regions to be processed to form the array region 102 (FIG. 1A) and the staircase regions 104 (FIG. 1A) previously described herein.

The sacrificial material of each of the preliminary tiers 125 of the preliminary stack structure 121 may be formed of and include at least one material (e.g., at least one insulative material) that may be selectively removed relative to the insulative material of the preliminary tiers 125 of the preliminary stack structure 121. The sacrificial material may be selectively etchable relative to the insulative material during common (e.g., collective, mutual) exposure to a first etchant; and the insulative material may be selectively etchable to the sacrificial material during common exposure to a second, different etchant. As used herein, a material is “selectively etchable” relative to another material if the material exhibits an etch rate that is at least about five times (5x) greater than the etch rate of another material, such as about ten times (10x) greater, about twenty times (20x) greater, or about forty times (40x) greater. By way of non-limiting example, depending on the material composition of the insulative material, the sacrificial material may be formed of and include one or more of at least one semiconductor material (e.g., silicon germanium (SiGe), polysilicon) at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and a MgOₓ), at least one dielectric nitride material (e.g., SiN_{y}), at least one dielectric oxynitride material (e.g., SiOₓN_{y}), at least one dielectric oxycarbide material (e.g., SiOₓC_{y}), at least one hydrogenated dielectric oxycarbide material (e.g., SiCₓO_{y}H_{z}), at least one dielectric carboxynitride material (e.g., SiOₓC_{z}N_{y}). In some embodiments, the sacrificial material of each of the preliminary tiers 125 of the preliminary stack structure 121 is formed of and includes at least one semiconductive material suitable for use as an channel material for the access devices 112 (FIGS. 1A and 1B) formed within the array region 102 (FIG. 1A) of the microelectronic device structure 100. For example, the sacrificial material may, for example, be formed of and include SiGe.

The staircase structures 130 (FIG. 1A) of the microelectronic device structure 100 may be formed using one or more material removal (e.g., patterning) processes. In some embodiments, upper surfaces of the preliminary stack structure 121 are patterned to form openings (e.g., central openings) including an initial central portion 148′, which openings may be used during formation of subsequently formed staircase structures 130 (see FIG. 2B). The initial central portion 148′ of the openings may be formed by, for example, forming and patterning one or more mask materials over the microelectronic device structure 100 and exposing the microelectronic device structure 100 to suitable etchants. By way of non-limiting example, an uppermost material of the preliminary stack structure 121 may be patterned (e.g., masked, photoexposed, developed, and etched) to form the initial central portions 148′.

As shown in FIG. 2A, the remaining portions of the uppermost material of the preliminary stack structure 121 may include a preliminary bridge 149. At the processing stage depicted in FIG. 2A, the preliminary bridge 149 may include a single, continuous portion of the uppermost material of the preliminary stack structure 121 substantially surrounding individual initial central portions 148′. The initial central portions 148′ may be discrete openings separated by the remaining portions of the uppermost material of the preliminary stack structure 121. Accordingly, the initial central portions 148′ may be discontinuous and discrete from one another in each of the X-direction and the Y-direction. For example, the remaining portions of the uppermost material of the preliminary stack structure 121 horizontally intervene (e.g., in the X-direction, in the Y-direction) between the initial central portions 148′. Accordingly, the initial central portions 148′ may be considered to be formed of and include multiple openings separated from one another by intervening portions of preliminary bridge 149, at the processing stage of FIG. 2A.

The initial central portions 148′ may include elliptical (e.g., circular) openings separated from one another in the X-direction and in the Y-direction. The initial central portions 148′ may individually be horizontally bounded by a single, closed curve shape. In some embodiments, the initial central portions 148′ individually exhibit a lateral dimension (e.g., a length) in the second horizontal direction (e.g., the Y-direction) that is larger than another lateral dimension (e.g., a width) in the first horizontal direction (e.g., the X-direction). At least some (e.g., each) of the initial central portions 148′ may exhibit a substantially elliptical (e.g., oblong, oval) horizontal cross-sectional shape. In other embodiments, the initial central portions 148′ may individually exhibit a substantially circular horizontal cross-sectional shape or a different closed curve horizontal cross-sectional shape (e.g., a horizontal cross-sectional shape, a rhombus horizontal cross-sectional shape, a rectangular horizontal cross-sectional shape, a square horizontal cross-sectional shape, a triangular horizontal cross-sectional shape).

With continued reference to FIG. 2A, some of the initial central portions 148′ may be aligned with each other (e.g., in the Y-direction) and other of the initial central portions 148′ may be offset from each other (e.g., in the Y-direction). The initial central portions 148′ may be arranged in a weave pattern (e.g., a hexagonal pattern, a hexagonal close-packed pattern), which may facilitate an increased density of the staircase structures 130 (FIG. 1A) within the staircase regions 104 (FIG. 1A). The initial central portions 148′ may be arranged in rows extending in the first horizontal direction (e.g., the X-direction) and columns extending in the second horizontal direction (e.g., the Y-direction). In some embodiments, each of the initial central portions 148′ in an individual column may be substantially horizontally offset (e.g., in each of the X-direction and the Y-direction) from each of the initial central portions 148′ in a horizontally neighboring (e.g., in the X-direction) column. In addition, at least one odd column of the initial central portions 148′ may include initial central portions 148′ substantially horizontally aligned (e.g., in the Y-direction) with the initial central portions 148′ of at least one other odd column of the initial central portions 148; and at least one even column of the initial central portions 148′ may include initial central portions 148′ substantially horizontally aligned (e.g., in the Y-direction) with the initial central portions 148′ of at least one other even column of the initial central portions 148′.

Similarly, each of the initial central portions 148′ of an individual row may be substantially horizontally offset (e.g., in each of the X-direction and the Y-direction) from each of the initial central portions 148′ in a horizontally neighboring (e.g., in the Y-direction) row. In addition, at least one odd row of the initial central portions 148′ may include initial central portions 148′ substantially horizontally aligned (e.g., in the X-direction) with the initial central portions 148′ of at least one other odd row of the initial central portions 148; and at least one even row of the initial central portions 148′ may include initial central portions 148′ substantially horizontally aligned (e.g., in the X-direction) with the initial central portions 148′ of at least one other even row of the initial central portions 148′. Accordingly, the initial central portions 148′ may be horizontally staggered from one another (e.g., offset from one another in each of the X-direction and the Y-direction). However, the disclosure is not so limited and the initial central portions 148′ may be arranged in other patterns (e.g., lines wherein the initial central portions 148′ of each line are aligned with the initial central portions 148′ of each of the other lines). In some embodiments, each initial central portion 148′ may be surrounded by six (6) other initial central portions 148′ and may be arranged in a hexagonal pattern.

Individual openings of each of the initial central portions 148′ may have substantially the same dimensions (e.g., lateral dimensions), and may be regularly spaced by substantially the same distance. Accordingly, a pitch between the initial central portions 148′ may be substantially uniform throughout the preliminary stack structure 121. The dimensions and spacing of the initial central portions 148′ may be selected to provide desired lateral dimensions and lateral spacing to features to be subsequently formed in the microelectronic device structure 100, as described below.

Referring to FIG. 2B, following formation of the initial central portions 148′ (FIG. 2A), initial staircase structures 130′ may individually be formed to include initial steps 132′ comprising edges (e.g., multi-directional horizontal ends) of the preliminary tiers 125 (including the sacrificial material and the insulative material thereof) of the preliminary stack structure 121. The initial staircase structures 130′ include a stepped cross-sectional profile in each of the ZX-plane and the ZY-plane, as shown in the perspective view of FIG. 2B. The stepped cross-sectional profile of the initial staircase structures 130′ may be defined by the geometric configurations of the initial steps 132′ of the initial staircase structures 130′. For clarity and ease of understanding the description, FIG. 2B illustrates only a particular quantity (e.g., five (5)) of the initial steps 132′ in the initial staircase structures 130′, however it will be understood that the initial staircase structures 130′ may include fewer or, alternatively, a greater quantity of the initial steps 132′ than those illustrated.

During formation of the initial staircase structures 130′, a portion of one or more mask materials may be patterned to expand openings in the mask materials and expose portions of an uppermost preliminary tier 125 of the preliminary stack structure 121. For example, openings in the mask materials used to form the initial central portions 148′ (FIG. 2A) may be expanded (e.g., in each of the X-direction and the Y-direction, in elliptical patterns) to form enlarged openings. The uppermost preliminary tier 125 and another preliminary tier 125 (e.g., vertically underlying the uppermost preliminary tier 125) may be exposed to etch chemistries through the openings to remove portions of the uppermost preliminary tier 125 exposed through the openings, as well as to remove portions of the other preliminary tier 125 (e.g., a second preliminary tier 125) at locations of the initial central portions 148′.

After removing the exposed portions of the uppermost preliminary tier 125 and the other preliminary tier 125 through the openings, the mask materials may be exposed to an etch chemistry to remove (e.g., trim) additional portions of the mask materials and expose additional portions of the uppermost preliminary tier 125 corresponding to a desired width (in the X-direction) and a desired length (in the Y-direction) of the initial steps 132′ of the initial staircase structures 130′ to be formed. After exposing the additional portions of the uppermost preliminary tier 125, the preliminary stack structure 121 is exposed to etch chemistries to remove portions of the uppermost preliminary tier 125, as well as to remove portions of additional preliminary tier 125 (e.g., the second preliminary tier 125, a third preliminary tier 125) through the enlarged openings in the mask materials and form additional initial steps 132′.

The process of trimming the mask materials and etching the preliminary tier 125 may be repeated a desired number of times to form the initial staircase structures 130′ (e.g., elliptical stadium structures). Trimming the mask materials and etching the preliminary tier 125 may be performed in a manner that radiates (e.g., diverges) laterally outward from the central portions 148 during formation of the initial steps 132′. With each sequential trimming of the mask materials and etching of the preliminary tier 125, the central portions 148 of the initial staircase structures 130′ may be vertically recessed relative to surrounding initial steps 132′, such that the central portions 148 serve as the lowermost initial step 132′ of each of the initial staircase structures 130′, and the surrounding initial steps 132′ are progressively vertically elevated relative to the central portions 148. As such, a lowermost preliminary tier 125 exposed during formation of the initial staircase structures 130′ is configured as the central portions 148 thereof, and the initial steps 132′ laterally surrounding the central portions 148 successively increase in vertical position as the initial steps 132′ extend laterally outward from the central portions 148 to the preliminary bridges 149. Accordingly, the central portions 148 of the initial staircase structures 130′ may be located at locations corresponding to the locations of the initial central portions 148′ (FIG. 2A) with the exception of being below (e.g., vertically recessed relative to) the initial central portions 148′ as a result of material removal processes used to form the initial staircase structures 130′.

With continued reference to FIG. 2B, each initial staircase structure 130′ may exhibit both a positive slope and a negative slope in each of the X-direction and the Y-direction. In some such embodiments, each initial staircase structure 130′ exhibits both a positive slope and a negative slope in additional directions (e.g., at acute angles to each of the X-direction and the Y-direction), such as when the initial staircase structures 130′ exhibit an elliptical (e.g., circular) horizontal cross-sectional shape. As used herein, the term “ellipse” means and includes a plane curve surrounding two focal points, such that for all points on the curve, the sum of the two distances to the focal points is a constant. As such, the term ellipse generalizes a circle, which is a special type of an ellipse in which the two focal points are the same. As used herein, the term “elliptical” means and includes a feature (e.g., material, region, structure) having the shape of an ellipse. Since the initial central portions 148′ (FIG. 2A) include the openings having closed curve horizontal cross-sectional shapes (e.g., elliptical horizontal cross-sectional shapes) that are separated from one another in the X-direction and in the Y-direction, the initial steps 132′ of the initial staircase structures 130′ extend from the central portions 148 thereof in more than one direction. The preliminary tiers 125 of the preliminary stack structure 121 may be subjected to material removal processes to expand (e.g., increase) horizontal dimensions of the openings of the initial central portions 148′ in each of the X-direction and the Y-direction, as well as in all horizontal directions therebetween. Accordingly, different vertical levels within an individual initial staircase structure 130′ may individually be formed to exhibit closed curve horizontal cross-sectional shapes (e.g., elliptical horizontal cross-sectional shapes), with relatively vertically lower portions of the initial staircase structure 130′ having relatively small horizontal cross-sectional areas than relatively vertically higher portions of the initial staircase structure 130′.

In some embodiments, the initial steps 132′ of the initial staircase structures 130′ individually include linear portions 133. Each linear portion 133 may separate two neighboring linear portions 133. For example, individually angled portions of the initial steps 132′ may be substantially linear and arranged horizontally adjacent to one another in the X-direction and in the Y-direction, as well as at acute angles relative to each of the X-direction and the Y-horizontal direction and form a closed curve horizontal cross-sectional shape (e.g., a generally elliptical horizontal cross-sectional shape). The initial steps 132′ may individually include substantially linear portions intersecting one another at intersections and separated by abrupt transitions therebetween. The linear portions 133 of the individual initial steps 132′ may be responsive to forming individually angled linear portions in the openings of the mask materials used to form the initial steps 132′. In other embodiments, the initial steps 132′ of the initial staircase structures 130′ individually include arcuate portions 135. The initial steps 132′ may individually include a single, closed-curve-shaped horizontal boundary, such that an individual initial step 132′ has a closed curve horizontal cross-sectional shape. The arcuate portions 135 of the individual initial steps 132′ may be responsive to forming arcuate portions in the openings of the mask materials used to form the initial steps 132′.

Some of the initial staircase structures 130′ may be aligned with each other (e.g., in the Y-direction) and other of the initial staircase structures 130′ may be offset from each other (e.g., in the Y-direction), responsive to the weave pattern of the initial central portion 148′ (FIG. 2A). The initial staircase structures 130′ may be arranged in the weave pattern (e.g., a hexagonal pattern, such as a hexagonal close-packed pattern), which may facilitate an increased density of subsequently formed staircase structures within the staircase regions 104 (FIG. 1A). The initial staircase structures 130′ may be arranged in rows extending in the first horizontal direction (e.g., the X-direction) and columns extending in the second horizontal direction (e.g., the Y-direction). In some embodiments, each of the initial staircase structures 130′ in an individual column may be substantially horizontally offset (e.g., in each of the X-direction and the Y-direction) from each of the initial staircase structures 130′ in a horizontally neighboring (e.g., in the X-direction) column. In addition, at least one odd column of the initial staircase structures 130′ may include initial staircase structures 130′ substantially horizontally aligned (e.g., in the Y-direction) with the initial staircase structures 130′ of at least one other odd column of the initial staircase structures 130; and at least one even column of the initial staircase structures 130′ may include initial staircase structures 130′ substantially horizontally aligned (e.g., in the Y-direction) with the initial staircase structures 130′ of at least one other even column of the initial staircase structures 130′.

Similarly, each of the initial staircase structures 130′ of an individual row may be substantially horizontally offset (e.g., in each of the X-direction and the Y-direction) from each of the initial staircase structures 130′ in a horizontally neighboring (e.g., in the Y-direction) row. In addition, at least one odd row of the initial staircase structures 130′ may include initial staircase structures 130′ substantially horizontally aligned (e.g., in the X-direction) with the initial staircase structures 130′ of at least one other odd row of the initial staircase structures 130; and at least one even row of the initial staircase structures 130′ may include initial staircase structures 130′ substantially horizontally aligned (e.g., in the X-direction) with the initial staircase structures 130′ of at least one other even row of the initial staircase structures 130′. Accordingly, the initial staircase structures 130′ may be horizontally staggered from one another (e.g., offset from one another in each of the X-direction and the Y-direction). However, the disclosure is not so limited and the initial staircase structures 130′ may be arranged in other patterns (e.g., lines wherein the initial staircase structures 130′ of each line are aligned with the initial staircase structures 130′ of each of the other lines). In some embodiments, each of the initial staircase structures 130′ is surrounded by six (6) other initial staircase structures 130′ and may be arranged in a hexagonal pattern.

As shown in FIG. 2B, individual initial staircase structures 130′ include the initial central portion 148′ partially defined by a lowermost preliminary tier 125 exposed during formation of the initial staircase structures 130′ and the preliminary bridge 149 partially defined by the uppermost preliminary tier 125. Further, portions of the uppermost preliminary tier 125 defining the uppermost initial steps 132′ of the initial staircase structures 130′ may be common among (e.g., shared by) multiple (e.g., two, three, four) of the neighboring initial staircase structures 130′. Thus, remaining portions of the uppermost preliminary tier 125 separate the neighboring initial staircase structures 130′ from one another. In some embodiments, at least some of the preliminary bridges 149 are individually defined by four (4) of the neighboring initial staircase structures 130′, such as within central portions of the staircase regions 104 (FIG. 1A), and defined by two (2) or three (3) of the initial staircase structures 130′, such as proximal peripheral edges of the staircase regions 104.

In some embodiments, portions of the initial staircase structures 130′ horizontally overlap (e.g., in the X-direction, in the Y-direction) one another, as described above. In some embodiments, one or more of the upper initial steps 132′ (e.g., a first initial step 132′ of the preliminary bridges 149, a second initial step 132′) of an individual initial staircase structures 130′ horizontally overlap one or more of the upper initial steps 132′ of another initial staircase structures 130′. For example, one or more of the upper initial steps 132′ of a first initial staircase structure 130′ may horizontally overlap additional upper initial steps 132′ of a second initial staircase structure 130′ horizontally neighboring the first initial staircase structure 130′. In some embodiments, at least a portion of an individual initial staircase structure 130′ (e.g., the central portion 148) does not horizontally overlap at least a portion of a neighboring initial staircase structure 130′. For example, the central portions 148 of neighboring initial staircase structures 130′ may be horizontally offset (e.g., in each of the X-direction and the Y-direction) from one another.

Referring to next FIG. 2C, at least one additional material removal process (e.g., chopping process) may be performed to at least partially shift the vertical elevation of at least some of the initial staircase structures 130′ (FIG. 2B) and form the staircase structures 130 (including the steps 132) previously described with reference to FIGS. 1A through 1C. For example, at least some portions of individual initial staircase structures 130′ may extended vertically deeper (e.g., in the Z-direction) into the preliminary stack structure 121 (FIG. 2B) relative to at least some portions of the initial staircase structures 130′ and relative to at least some of portions of others of the initial staircase structures 130′. In addition, trenches (e.g., slots, slits) may be formed to vertically extend through the preliminary stack structure 121, and the preliminary stack structure 121 may be subjected to so-called replacement gate processing to form the vertical stack structure 122 including the vertically alternating sequence of the second conductive structures 140 and the second insulative material 124. The replacement gate processing may replace portions of the sacrificial material of the preliminary tiers 125 (FIG. 2B) of the preliminary stack structure 121 (FIG. 2B) with conductive material to form the second conductive structures 140, as described in further detail below. In addition, the conductive contact structure 142 may be formed to contact the second conductive structures 140 at the steps 132 of the staircase structures 130, as also described in further detail below.

The additional material removal processes (e.g., one or more chopping processes) may increase the depth(s) (e.g., in the Z-direction) of at least some portions of some of the staircase structures 130 relative to an upper surface of the preliminary stack structure 121 (FIG. 2B), to at least partially re-position the portion(s) of the some of the staircase structures 130 at various (e.g., progressively descending) levels 152 (e.g., vertical elevations), as shown in FIG. 2C. The additional material removal processes may permit lower boundaries of some of the staircase structures 130 to be positioned more proximate a lower boundary of the vertical stack structure 122 than some others of the staircase structures 130. Additional portions of the staircase structures 130 may be positioned proximal an upper boundary of the vertical stack structure 122 (e.g., at an uppermost level 152), and further portions of the staircase structures 130 may be positioned at various levels 152 between the lowermost level 152 and the uppermost level 152. The staircase structures 130 may individually be located on one or more (e.g., two, three) of the levels 152 including a stepped cross-sectional profile in the ZX-plane, as shown in FIG. 2C.

In some embodiments, exposed side surfaces 154 defining the levels 152 of the vertical stack structure 122 formed from the preliminary stack structure 121 (FIG. 2B) include substantially linear, elongated portions vertically overlying at least some of the steps 132 of the staircase structures 130 at least partially within vertically neighboring levels 152. In some such embodiments, the levels 152 are formed using at least one material removal process (e.g., at least one chopping process) to terminate vertically below a location of the initial staircase structures 130′ (FIG. 2B) and form the staircase structures 130 at the levels 152. In some embodiments, the levels 152 are formed to descend with increased distance from the array region 102 (FIG. 1A) in the first horizontal direction (e.g., the X-direction) and elongated portions of the levels 152 extend in the second horizontal direction (e.g., the Y-direction). The elongated portions of the levels 152 extend in a direction that is transverse to a direction in which the first conductive structures 120 (FIG. 1A) extend through the array region 102. Further, elongated portions of the staircase structures 130 may be substantially parallel with the elongated portions of the levels 152 in the Y-direction. Since the staircase structures 130 are located on one or more of the levels 152 and include portions of the steps 132 extending in the X-direction and additional portions of the steps 132 extending in the Y-direction, the vertical stack structure 122 decreases in vertical height along the first horizontal direction and along the second horizontal direction.

In some embodiments, different horizontal portions of an individual staircase structure 130 are formed to be vertically offset from one another so as to span across multiple individual levels 152. Different horizontal portions of the staircase structure 130 may be located within different levels 152 of the vertical stack structure 122 than one another, as shown in FIG. 2C. For example, different horizontal portions of an individual staircase structure 130 may be vertically offset from one another (e.g., vertically segmented) by an individual level 152 at a location of the uppermost step 132 (e.g., the bridge 150) thereof or, alternatively, at a location of the lowermost step 132 (e.g., the central portion 148) thereof. In some embodiments, different horizontal portions of an individual staircase structures 130 are vertically offset from one another by one or more individual levels 152 at a location of the second step 132 (e.g., adjacent to the uppermost step 132 of the bridge 150) thereof. In other embodiments, different horizontal portions of an individual staircase structure 130 are vertically offset from one another by one or more individual levels 152 at a location of the uppermost step 132 thereof, and all other steps 132 below the uppermost step 132 are substantially continuous, although other configurations are contemplated. Since the elongated portions of the staircase structures 130 are substantially parallel with the elongated portions of the levels 152 in the Y-direction, the steps 132 extending in the X-direction are not segmented by the levels 152. Thus, the staircase structures 130 may exhibit a staggered (e.g., descending) slope among two or more of the levels 152.

With continued reference to FIG. 2C, following formation of the staircase structures 130 (including the steps 132 thereof) and the levels 152 within the preliminary stack structure 121 (FIG. 2B), the third insulative material 134 (FIGS. 1B and 1C) may be formed over the steps 132 of the staircase structures 130, and the fourth insulative material 137 (FIGS. 1B and 1C) may be formed over the third insulative material 134. Thereafter, slots (e.g., slits, trenches) may be formed to vertically extend through the fourth insulative material 137 (FIGS. 1B and 1C), the third insulative material 134 (FIGS. 1B and 1C), and the preliminary stack structure 121 (FIG. 2B), portions of the sacrificial material of the preliminary tiers 125 (FIG. 2B) of the preliminary stack structure 121 (FIG. 2B) may be selectively exhumed through the slots, and then the dielectric material 128 (FIGS. 1B and 1C) and the second conductive structures 140 (and the first conductive structures 120 (FIGS. 1A and 1B)) may be formed within the resulting recesses (e.g., void spaces) within the sacrificial material to form the vertical stack structure 122 (including the tiers 131 thereof previously described herein with reference to FIGS. 1B and 1C). Thereafter, the slots may be filled within insulative material to form isolation structures 158 (FIG. 2I) therein.

The slots formed within the preliminary stack structure 121 (FIG. 2B) may have geometric configurations and horizontal positions corresponding to those of the isolation structures 158 (FIG. 2I) described in further detail below with reference to FIG. 2I. The configurations and positions of the slots may facilitate multidirectional horizontal pathing of the second conductive structures 140 formed by way of replacement gate processing using the slots. The horizontal pathing and geometric configurations of the second conductive structures 140 are described in further detail below with reference to FIGS. 2D through 2J. Following the formation of the slots within the preliminary stack structure 121 (FIG. 2B), the replacement gate processing may include treating portions of the preliminary stack structure 121 exposed within the slots with at least one wet etchant formulated to selectively remove portions of the sacrificial material of the preliminary tiers 125 (FIG. 2B) of the preliminary stack structure 121 through the slots. The wet etchant may be selected to remove the portions of the sacrificial material without substantially removing portions of the sacrificial material of the preliminary tiers 125 of the preliminary stack structure 121. Remaining portions of the insulative material of the preliminary tiers 125 of the preliminary stack structure 121 may form the second insulative material 124 (FIGS. 1B and 1C) of the tiers 131 of the vertical stack structure 122. In some embodiments wherein the sacrificial material comprises semiconductive material (e.g., SiGe) and the insulative material and comprises dielectric oxide material (e.g., SiOₓ, such as SiO₂), portions of the sacrificial material proximate the slots are selectively removed using a wet etchant comprising tetra-methyl ammonium hydroxide (TMAH). Following the selective removal of the portions of the sacrificial material, the resulting recesses may be filled with insulative material and conductive material to form the dielectric material 128, the second conductive structures 140, and the first conductive structures 120 (FIGS. 1A and 1B). The second conductive structures 140 and the first conductive structures 120 may be formed substantially simultaneously with one another through the replacement gate process.

Following the formation of the vertical stack structure 122, the conductive contact structures 142 may be formed in contact openings formed to extend through the third insulative material 134 and the fourth insulative material 137. For example, portions of each of the third insulative material 134 and the fourth insulative material 137 may be selectively removed and conductive material may be formed (e.g., delivered, deposited) within the contact openings to form the conductive contact structures 142. The conductive contact structures 142 may be formed to contact (e.g., physically contact, electrically contact) individual second conductive structures 140 of the tiers 131 of the vertical stack structure 122 at the steps 132 of the staircase structures 130. For example, the conductive contact structures 142 may individually physically contact (e.g., land on) portions of upper surfaces of the second conductive structures 140 at least partially defining treads of the steps 132. For clarity and ease of understanding the drawings and associated description, surrounding materials, including the third insulative material 134 and the fourth insulative material 137, are omitted in FIG. 2C.

As described above, the staircase structures 130 may individually exhibit one or more closed curve horizontal cross-sectional shape(s). As used herein, the term “closed curve horizontal cross-sectional shape” means and includes a horizontal cross-sectional shape having horizontal boundaries defined by a curve that has no endpoints and that completely encloses a horizontal area. The curve may include arcuate (e.g., non-linear) portions and/or linear (e.g., non-arcuate) portions. A feature (e.g., structure, material, region) having a closed curve horizontal cross-sectional shape may have horizontal boundaries at least partially defined by horizontal boundaries of one or more additional features (e.g., structures, materials, regions) that interact with the feature within a horizontal plane (e.g., an XY-plane) of the closed curve horizontal cross-sectional shape. For example, at a particular vertical elevation, an individual staircase structure 130 may have a closed curve horizontal cross-sectional shape defined by a curve having portions defined by horizontal ends (e.g., side surfaces) of the vertical stack structure 122 and horizontal ends (e.g., side surfaces) of one or more of the isolation structures 158 (FIG. 2I). A feature may exhibit a single (e.g., only one) closed curve horizontal cross-sectional shape at different vertical elevations thereof, and/or may exhibit multiple (e.g., more than one) different closed curve horizontal cross-sectional shapes at different vertical elevations thereof.

Since the staircase structures 130 may individually exhibit a closed curve horizontal cross-sectional shape (e.g., an elliptical horizontal cross-sectional shape), the steps 132 thereof may be defined by at least partially non-linear (e.g., arcuate) horizontal ends of the tiers 131 of the vertical stack structure 122. An individual staircase structure 130 may be formed to span a complete angle (e.g., a 360-degree angle) from a vertical centerline of the central portion 148 thereof. Accordingly, for an individual staircase structure 130, the steps 132 thereof individually include first portions 132a extending in the first horizontal direction (e.g., the X-direction), second portions 132b extending in the second horizontal direction (e.g., the Y-direction), and third portions 132c between the first portions 132a and the second portions 132b and extending at an acute angle relative to the first horizontal direction and the second horizontal direction.

The conductive contact structures 142 may be arranged in rows extending in the second horizontal direction (e.g., the Y-direction). Individual rows of the conductive contact structures 142 may be substantially parallel with one another, as described below. In some embodiments, the conductive contact structures 142 are arranged in the rows on portions of the steps 132 extending in the X-direction (e.g., the first portion 132a of the steps 132), without being arranged in the rows on portions of the steps 132 extending in the Y-direction (e.g., the second portion 132b of the steps 132). The individual rows of the conductive contact structures 142 may extend in the Y-direction, without extending in the X-direction, although other configurations may be contemplated so long as the conductive contact structures 142 at a single step 132 are individually associated with only one of the second conductive structures 140. Since the elongated portions of the staircase structures 130 are substantially parallel with the elongated portions of the levels 152 in the Y-direction and the steps 132 extending in the X-direction are not segmented by the levels 152, individual rows of the conductive contact structures 142 are not segmented by the levels 152. Accordingly, the conductive contact structures 142 of an individual row may be located within a single level 152.

Although FIG. 2C illustrates a particular quantity of the conductive contact structures 142 aligned in rows within some of the staircase structures 130, it will be understood that the quantity of the conductive contact structures 142 is shown for illustrative purposes only and that the microelectronic device structure 100 may include additional rows of the conductive contact structures 142 within additional staircase structures 130 within the levels 152. For example, neighboring staircase structures 130 may also include rows of the conductive contact structures 142, and the staircase structures 130 may individually include more than one row (e.g., two rows) of the conductive contact structures 142, as described in further detail below.

With reference to FIG. 2D, and as previously described, the vertical stack structure 122 within the staircase regions 104 (FIG. 1A) may include the second conductive structures 140 vertically overlying (e.g., in the Z-direction) the base structure 110 and within horizontal boundaries (e.g., in the X-direction, in the Y-direction) of one another. The vertical stack structure 122 includes levels of the second conductive structures 140 vertically spaced (e.g., in the Z-direction) from one another. For clarity and ease of understanding the drawings and associated description, surrounding materials including the vertically intervening insulative materials (e.g., the dielectric material 128, the second insulative material 124) are omitted in FIG. 2D. As illustrated in the perspective view of FIG. 2D, the second conductive structures 140 may individually be formed to exhibit multi-directional (e.g., non-linear) horizontal pathing. For example, the second conductive structures 140 may individually include first portions extending in the first horizontal direction (e.g., the X-direction) and second portions horizontally adjacent to the first portions and extending in the second horizontal direction (e.g., the Y-direction).

Horizontal areas of relatively vertically lower second conductive structures 140 may be greater than horizontal areas of relatively vertically higher second conductive structures 140. An individual second conductive structure 140 vertically positioned relatively father away from the base structure 110 may exhibit a smaller horizontal area than another individual second conductive structure 140 vertically positioned relatively closer to the base structure 110. In some embodiments, the steps 132 of the staircase structures 130 vertically descend (e.g., in the Z-direction) in the second horizontal direction (e.g., in the Y-direction) substantially transverse to a direction in which the first conductive structures 120 (FIG. 1A) extend within the array region 102 (FIG. 1A). Further, the steps 132 of the staircase structures 130 vertically descend in the first horizontal direction (e.g., in the X-direction) away from the array region 102 and substantially parallel to the direction in which the first conductive structures 120 horizontally extend.

Referring next to FIG. 2E, the multi-directional horizontal pathing exhibited by the second conductive structures 140, in combination with the weave pattern of the staircase structures 130 may separate (e.g., physically separate) the conductive contact structures 142 (FIG. 2D) from one another by one or more desired distances. An enlarged portion of the multi-directional pathing of the second conductive structures 140 is illustrated in image A of FIG. 2E, an enlarged portion of the weave pattern of the staircase structures 130 is illustrated in image B, and a combination of the enlarged portions of the multi-directional pathing of the second conductive structure 140 and the staircase structures 130 is illustrated in image C. For clarity and ease of understanding the drawings and associated description, surrounding materials, including additional materials of the vertical stack structure 122, are omitted in the top-down views of the images A, B, C of FIG. 2E.

As shown in image A of FIG. 2E, the second conductive structures 140 may individually include first portions 140a extending in the first horizontal direction (e.g., the X-direction) and second portions 140b horizontally adjacent to the first portions 140a and extending in the second horizontal direction (e.g., the Y-direction). The first portions 140a and the second portions 140b of the second conductive structures 140 may be substantially traverse (e.g., perpendicular) to one another. In some embodiments, the second conductive structures 140 include substantially linear portions intersecting one another at intersections 141 and separated by abrupt transitions therebetween. The second portions 140b may be integral and continuous with the first portions 140a. Accordingly, the first portions 140a and the second portions 140b of the second conductive structures 140 together may form continuous portions of non-linear structures having sharp corners at the intersections 141 between individual linear portions thereof. In some embodiments, each of the first portions 140a and the second portions 140b of the second conductive structures 140 comprise substantially equal lengths. In additional embodiments, some of the first portions 140a of the second conductive structures 140, optionally, include arcuate (e.g., non-linear) portions, as described in greater detail below with reference to FIG. 2I.

As shown in image B of FIG. 2E, and as described above, the staircase structures 130 may include one or more closed curve horizontal cross-sectional shapes (e.g., elliptical horizontal cross-sectional shapes) separated from one another in the X-direction and in the Y-direction and arranged in the weave pattern. The staircase structures 130 individually include the central portion 148 (e.g., the lowermost step 132 thereof) and the bridge 150 (e.g., the uppermost step 132 thereof). Additional steps 132 may be located between the central portion 148 and the bridge 150. For example, the additional steps 132 may radiate (e.g., diverge) laterally outward from the central portions 148, as illustrated by arrows 151. Although images B and C of FIG. 2E illustrate that the staircase structures 130 individually comprise a particular quantity (e.g., three (3)) of the steps 132, for illustrative purposes, the staircase structures 130 may individually include additional steps 132.

In image C of FIG. 2E, the weave pattern of the staircase structures 130 is illustrated as being overlaid, for illustrative purposes, with the multi-directional pathing of the second conductive structure 140 of image A. In image C, the second conductive structure 140 is illustrated in dashed lines, for clarity, to illustrate a location of the second conductive structure 140 relative to locations of the staircase structures 130, although it is understood that the second conductive structures 140 are vertically segmented by the staircase structures 130 and the levels 152, as depicted in FIG. 2D. Since the second conductive structures 140 include substantially linear portions (e.g., the first portions 140a, the second portions 140b) intersecting one another at the intersections 141, one or more (e.g., two) of the intersections 141 may be vertically aligned with the central portions 148 of at least some (e.g., each) of the staircase structures 130 and one or more (e.g., two) additional intersections 141 may be vertically aligned with the bridges 150. Accordingly, the multi-directional horizontal pathing exhibited by the second conductive structures 140, in combination with the weave pattern of the staircase structures 130 exhibiting the substantially elliptical cross-sectional shape, may facilitate formation of the conductive contact structures 142 (FIG. 2D), such that the individual conductive contact structures 142 at a single step 132 of the staircase structures 130 are individually associated with only one of the second conductive structures 140.

As described above, the levels 152 of the vertical stack structure 122 (FIG. 2D) may be formed using one or more mask materials (e.g., a mask material 156) illustrated in dashed lines, for clarity, in image C of FIG. 2E to illustrate a location of the mask material 156 relative to the second conductive structure 140 and the staircase structures 130. Formation of the levels 152, in addition to the formation of second conductive structures 140 exhibiting multi-directional horizontal pathing and the formation of the staircase structures 130 in a weave pattern, may enhance separation of the conductive contact structures 142 (FIG. 2D) from one another by one or more desired distances (e.g., at varying heights) while providing a larger cross-sectional area for the conductive contact structures 142 on the individual steps 132 of the staircase structures 130.

FIG. 2F is a simplified, partial perspective view of the microelectronic device structure 100 illustrating a view similar to that of FIG. 2D, but including additional materials of the vertical stack structure 122. A location of the second conductive structures 140 is represented by a path 140′, illustrated in dashed lines, for clarity, to illustrate a location of the second conductive structures 140 relative to the steps 132 of the staircase structures 130 and the levels 152. Since the second conductive structures 140 individually exhibit multi-directional (e.g., non-linear) horizontal pathing, the path 140′ of the second conductive structures 140 illustrates a direction of the first portions 140a extending in the first horizontal direction (e.g., the X-direction) and the second portions 140b horizontally adjacent to the first portions 140a and extending in the second horizontal direction (e.g., the Y-direction). The first portions 140a of the second conductive structures 140 may be located within horizontal boundaries (e.g., in the X-direction) of one another, and the second portions 140b of the second conductive structures 140 may be located within horizontal boundaries (e.g., in the Y-direction) of one another. Further, the path 140′ may descend with increased distance from the array region 102 (FIG. 1A) in the first horizontal direction (e.g., the X-direction) responsive to the levels 152 descending with increased distance from the array region 102.

As shown in FIG. 2F, different groups of the second conductive structures 140 may terminate (e.g., be truncated) at different side surfaces 154 of the vertical stack structure 122 resulting from the formation of the levels 152. For an individual group of the second conductive structures 140 terminating at an individual side surface 154 of an individual level 152, additional groups of the second conductive structures 140 vertically underlying the group of the second conductive structures 140 may extend beyond the side surface 154 and may at least partially define the steps 132 of one of the staircase structures 130. The configuration of the second conductive structures 140 (e.g., collectively extending along the path 140′) facilitates formation of the conductive contact structures 142 (FIG. 2D) arranged in rows extending in the second horizontal direction (e.g., the Y-direction). The multi-directional (e.g., non-linear) horizontal pathing exhibited by the second conductive structures 140, in combination with the configurations (e.g., horizontal shapes) and arrangements (e.g., weave pattern) of the staircase structures 130, may facilitate a greater quantity of the conductive contact structures 142 to be located within the staircase regions 104 (FIG. 1A) as compared to conventional configurations, which may permit a greater quantity of the vertical stacks of memory cells 108 (FIG. 1A) to be located within the array region 102 (FIG. 1A) as compared to conventional configurations.

With collective reference to FIGS. 2G and 2H, enlarged portions of the staircase region 104 (FIG. 1A) including the staircase structures 130 are illustrated. FIG. 2G is a simplified, partial top-down views of a portion of the microelectronic device structure 100, and FIG. 2H is a simplified, partial cross-sectional view of a portion of the microelectronic device structure 100. For clarity and ease of understanding the description, surrounding materials, including the third insulative material 134 and the fourth insulative material 137, are omitted in FIGS. 2G and 2H. In addition, dimensional ranges of materials and/or structures of the disclosure may not reflect presence of additional materials and/or structures. For example, partitioning within an individual staircase structure 130 by an isolation structure 158 (FIG. 2I) is omitted for clarity purposes.

As shown in FIG. 2G, a maximum horizontal dimension, in a first horizontal direction, of the central portion 148 of an individual staircase structure 130 may be relatively less than another maximum horizontal dimension, in a second horizontal direction, of the central portion 148. For example, a first dimension D₁ (e.g., a width) in the X-direction of the central portion 148 of an individual staircase structure 130 may be within a range of from about 180 nanometers (nm) to about 320 nm, such as from about 180 nm to about 220 nm, from about 220 nm to about 260 nm, or from about 260 nm to about 320 nm; and a second dimension D₂ (e.g., a length) in the Y-direction of the central portion 148 thereof may be within a range of from about 280 nm to about 420 nm, such as from about 280 nm to about 320 nm, from about 320 nm to about 360 nm, or from about 360 nm to about 420 nm. However, the disclosure is not so limited, and the first dimension D₁ and/or the second dimension D₂ may individually be different than the values described above. In some embodiments, the second dimension D₂ is greater than the first dimension D₁. In other embodiments, the second dimension D₂ is substantially equal to the first dimension D₁, such as when an individual staircase structure 130 exhibits a substantially circular horizontal cross-sectional shape.

The staircase structures 130 may be substantially uniformly (e.g., evenly) horizontally spaced (e.g., in the X-direction, in the Y-direction) from one another. In some embodiments, a third dimension D₃ (e.g., a pitch) between staircase structures 130 horizontally neighboring one another in the X-direction may be within a range of from about 1.5 micrometers (μm) to about 2.5 μm, such as from about 1.5 μm to about 1.8 μm, from about 1.8 μm to about 2.1 μm, or from about 2.1 μm to about 2.5 μm. However, the disclosure is not so limited, and the third dimension D₃ may be different than the values described above. In some embodiments, a fourth dimension D₄ (e.g., a pitch) between staircase structures 130 horizontally neighboring one another in the Y-direction may be within a range of from about 1.7 μm to about 2.7 μm, such as from about 1.7 μm to about 2 μm, from about 2 μm to about 2.3 μm, or from about 2.3 μm to about 2.7 μm. However, the disclosure is not so limited and the fourth dimension D₄ may be different than the values described above. In some embodiments, the fourth dimension D₄ is greater than the third dimension D₃. In some embodiments, the fourth dimension D₄ corresponds to a horizontal pitch (e.g., in the Y-direction) between first conductive structures 120 (FIG. 1A) of the array region 102 (FIG. 1A) horizontally neighboring one another in the Y-direction.

In addition, a fifth dimension D₅ (e.g., a pitch) between centerlines C_{L} in the X-direction of staircase structures 130 of horizontally neighboring columns of the staircase structures 130 may be within a range of from about 0.5 μm to about 1.5 μm, such as from about 0.5 μm to about 0.8 μm, from about 0.8 μm to about 1.1 μm, or from about 1.1 μm to about 1.5 μm. However, the disclosure is not so limited and the fifth dimension D₅ may be different than the values described above. Further, a sixth dimension D₆ (e.g., a width in the X-direction, a width in the Y-direction) of a tread of an individual step 132 of the staircase structures 130 may be within a range of from about 50 nm to about 150 nm, such as from about 50 nm to about 75 nm, from about 75 nm to about 100 nm, from about 100 nm to about 125 nm, or from about 125 nm to about 150 nm. However, the disclosure is not so limited, and the sixth dimension D₆ may be different than the values described above.

As shown in FIG. 2H, a seventh dimension D₇ (e.g., a vertical height) in the Z-direction of an individual step 132 of the staircase structures 130 may be within a range of from about 75 nm to about 225 nm, such as from about 75 nm to about 100 nm, from about 100 nm to about 125 nm, from about 125 nm to about 150 nm, from about 150 nm to about 175 nm, from about 175 nm to about 200 nm, or from about 200 nm to about 225 nm. However, the disclosure is not so limited, and the seventh dimension D₇ may be different than the values described above. In some embodiments, the seventh dimension D₇ of an individual step 132 is substantially equal to each of the other steps 132. An eighth dimension D₈ (e.g., a vertical height) in the Z-direction of an individual level 152 of the vertical stack structure 122 may be within a range of from about 350 nm (e.g., about 0.35 μm) to about 1150 nm (e.g., about 1.15 μm), such as from about 350 nm to about 550 nm, from about 550 nm to about 750 nm, from about 750 nm to about 950 nm, or from about 950 nm to about 1150 nm. However, the disclosure is not so limited and the eighth dimension D₈ may be different than the values described above. Further, a ninth dimension D₉ (e.g., a width) in the X-direction of an individual level 152 of the vertical stack structure 122 may be within a range of from about 0.5 μm to about 1.5 μm, such as from about 0.5 μm to about 0.8 μm, from about 0.8 μm to about 1.1 μm, or from about 1.1 μm to about 1.5 μm. However, the disclosure is not so limited, and the ninth dimension D₉ may be different than the values described above. In some embodiments, the ninth dimension D₉ corresponds to (e.g., is substantially equal to) the fifth dimension D₅ between centerlines C_{L} of horizontally neighboring (e.g., in the X-direction) staircase structures 130 of horizontally neighboring columns.

Referring to FIG. 2I, enlarged portions of the array region 102 including the first conductive structures 120 (shown in dashed lines) and the staircase regions 104 including the staircase structures 130 and the second conductive structures 140 are illustrated. For clarity and ease of understanding the description, FIG. 2I does not illustrate other components of the microelectronic device structure 100, such as the vertical stacks of memory cells 108 within the array region 102. In addition, some materials, including the third insulative material 134 and the fourth insulative material 137, are omitted in the staircase regions 104 of FIG. 2I.

The second conductive structures 140 may include the first portions 140a extending in the first horizontal direction (e.g., the X-direction) and the second portions 140b horizontally adjacent to the first portions 140a and extending in the second horizontal direction (e.g., the Y-direction). In addition, the second conductive structures 140 may, optionally, include third portions 140c extending in the first horizontal direction (e.g., the X-direction) and substantially parallel to the first portions 140a. Some of the first portions 140a (e.g., every other first portion 140a) of the second conductive structures 140 are described herein as the third portions 140c, for illustrative purposes. Thus, one of the second portions 140b of the second conductive structures 140 may horizontally intervene between one of the first portions 140a and one of the third portions 140c.

In some embodiments, each of the first portions 140a and the second portions 140b include substantially linear portions of the second conductive structures 140, and the third portions 140c include arcuate (e.g., non-linear) portions thereof. Accordingly, the second conductive structures 140 may include substantially linear portions and arcuate portions intersecting one another at the intersections 141 and separated by abrupt transitions therebetween. For clarity and ease of understanding the drawings and associated description, the third portions 140c of the second conductive structures 140 are differentiated from the first portions 140a by their locations (e.g., laterally offset from the first conductive structures 120 in the Y-direction) and by their shape (e.g., exhibiting an arcuate shape). Each of the first portions 140a, the second portions 140b, and the third portions 140c of the second conductive structures 140 may include substantially the same material composition with no readily discernable physical interface therebetween.

As shown in FIG. 2I, horizontally neighboring pairs of the second conductive structures 140 (including first portions 140a, the second portions 140b, and the third portions 140c thereof) may be separated from one another by the isolation structures 158 horizontally intervening therebetween. The isolation structures 158 may comprise the slots previously described herein with reference to FIG. 2C filled (e.g., substantially filled) with one or more materials (e.g., insulative material). The isolation structures 158 may individually include first portions 158a extending in the first horizontal direction (e.g., the X-direction) and second portions 158b intersecting the first portions 158a at intersections 159 and extending in the second horizontal direction (e.g., the Y-direction). The first portions 158a and the second portions 158b of the isolation structures 158 may individually include substantially linear portions intersecting one another at the intersections 159. In some embodiments, the first portions 158a of the isolation structures 158 are between parallel extending segments (e.g., the first portions 140a) of the second conductive structures 140, and the second portions 158b of the isolation structures 158 intersect the first portions 158a thereof and extend substantially parallel to additional segments (e.g., the second portions 140b) of the second conductive structures 140 interleaved between the parallel extending segments thereof.

The isolation structures 158 may be formed of and include insulative material such as, for example, one or more of an oxide material (e.g., SiO₂, phosphosilicate glass, borosilicate glass, borophosphosilicate glass, fluorosilicate glass, TiO₂, HfO₂, ZrO₂, HfO₂, TaO₂, MgO, Al₂O₃, or a combination thereof), and amorphous carbon. In some embodiments, the isolation structures 158 comprise SiO₂.

The first portions 158a of the isolation structures 158 may individually exhibit an elongate shape having a length in the X-direction that is greater than a width in the Y-direction, and the second portions 158b of the isolation structures 158 may individually exhibit an elongate shape having a length in the Y-direction that is greater than a width in the X-direction. In some embodiments, the width of the first portions 158a of the isolation structures 158 in the Y-direction is less than the width of the second portions 158b thereof in the X-direction. By way of non-limiting example, the width of the first portions 158a may be within a range of from about 50 nm to about 150 nm, and the width of the second portions 158b may be within a range of from about 150 nm to about 450 nm. The isolation structures 158 may be sized and shaped to facilitate electrical isolation of groups of the second conductive structures 140 horizontally adjacent (e.g., in the Y-direction) opposing sides of the second conductive structures 140. In some embodiments, the first portions 158a of the isolation structures 158 are within horizontal boundaries of the lowermost steps 132 (e.g., the central portions 148) of the staircase structures 130. In some embodiments, transitions between neighboring levels 152 may be located along longitudinal centerlines (e.g., in the Y-direction) of the second portions 158b of the isolation structures 158. A first half of an individual second portion 158b of an individual isolation structure 158 may be within horizontal boundaries of a first level 152, and a second half of the second portion 158b thereof may be within horizontal boundaries of a second level 152, neighboring the first level 152.

In some embodiments, the first portions 140a of the second conductive structures 140 are proximal lateral sides of the first portions 158a of the isolation structures 158, the second portions 140b are proximate to lateral sides of the second portions 158b, and the third portions 140c are proximate to longitudinal ends of the second portions 158b. Arcuate-shaped portions (e.g., the third portions 140c) of the second conductive structures 140 may be adjacent to the longitudinal ends of the second portions 158b of the isolation structures 158, and substantially linear portions (e.g., the first portions 140a, the second portions 140b) thereof may be adjacent to the lateral sides of the first portions 158a and the second portions 158b, respectively, although other configurations may be contemplated. For convenience, only one of the second conductive structures 140 is illustrated adjacent to each of the isolation structures 158 within the staircase regions 104 in FIG. 2I, although it is understood that the staircase regions 104 may include additional (e.g., two) of the second conductive structures 140 on opposing sides of the isolation structures 158.

In some embodiments, a pattern of one of the second conductive structures 140 exhibits a so-called “mirror” pattern that is substantially symmetric to another one of the second conductive structures 140 with respect to the first portions 158a of the isolation structures 158. In addition, two neighboring second conductive structures 140 may exhibit a mirror pattern that is substantially symmetric with one another with respect to a phantom line extending in the X-direction at substantially equal distances (e.g., a horizontal midpoint) from the longitudinal ends of the second portions 158b of the isolation structures 158 (e.g., at substantially equal distances between neighboring first conductive structures 120 of the array region 102).

Additional benefits of the configuration of the second conductive structures 140 (e.g., non-linear conductive structures) as compared to linear conductive structures of conventional device structures, include reducing leakage as a result of coupling capacitance between neighboring conductive structures. Without being bound by any particular theory, it is believed that by reducing the surface area presented to neighboring conductive structures of the second conductive structures 140, undesirable leakage may be minimized (e.g., prevented). A reduced surface area of the third portions 140c (e.g., alone) of the second conductive structures 140 presented to other third portions 140c of neighboring second conductive structures 140 is significantly less than a surface area of a full length of conductive structures presented to a full length of neighboring linear conductive structures of conventional device structures.

As shown in FIG. 2I, the conductive contact structures 142 are arranged in rows (e.g., first rows 160, second rows 162) extending in the Y-direction and spaced apart from one another in the X-direction. The conductive contact structures 142 may be located at horizontal ends (e.g., lateral ends) of the second conductive structures 140. In some embodiments, each of the first rows 160 and the second rows 162 of the conductive contact structures 142 extend substantially transverse to a direction (e.g., the X-direction) in which the first conductive structures 120 extend within the array region 102, without extending substantially parallel to the direction in which the first conductive structures 120 extend. As such, each of the first rows 160 and the second rows 162 of the conductive contact structures 142 extend in a single horizontal direction (e.g., the Y-direction). The first rows 160 and the second rows 162 of the conductive contact structures 142 are located on the second portions 140b of the second conductive structures 140, without being located on the first portions 140a and the third portions 140c thereof.

The first rows 160 of the conductive contact structures 142 may horizontally extend in parallel with one another in the Y-direction. Pairs of the first rows 160 may horizontally overlap one another in the Y-direction, and may be separated from one another in the X-direction by the second portions 158b of the isolation structures 158. Similarly, the second rows 162 of the conductive contact structures 142 may also horizontally extend in parallel with one another in the Y-direction. Pairs of the second rows 162 may horizontally overlap one another in the Y-direction, and may be separated from one another in the X-direction and horizontally separated from one another by the second portions 158b of the isolation structures 158. Further, the first rows 160 may be substantially aligned with the second rows 162 in the X-direction. The second rows 162 may horizontally extend in series with the first rows 160 in the Y-direction.

With continued reference to FIG. 2I, the staircase structures 130 may individually include more than one (e.g., two) of the rows 160, 162 of the conductive contact structures 142 operatively associated therewith. In some embodiments, the staircase structures 130 individually include one of the first rows 160 and one of the second rows 162 substantially horizontally aligned with one another in the X-direction. The first rows 160 and the second rows 162 of the conductive contact structures 142 of an individual staircase structure 130 may be located within a single (e.g., only one) level 152 of the vertical stack structure 122.

In some embodiments, more than one (e.g., two) of the conductive contact structures 142 are located on an individual step 132 of an individual staircase structure 130. For example, an uppermost conductive contact structure 142 within one of the first rows 160 and an uppermost conductive contact structure 142 within one of the second rows 162 may each be located on the uppermost step 132 (e.g., the bridge 150) of an individual staircase structure 130. Further, a lowermost conductive contact structure 142 within the one of the first rows 160 and a lowermost conductive contact structure 142 within the one of the second rows 162 may each be located on the lowermost step 132 (e.g., the central portion 148) of the individual staircase structure 130. Additional conductive contact structures 142 between the uppermost and the lowermost conductive contact structures 142 of the rows 160, 162 may be similarly arranged (e.g., two of the conductive contact structures 142 on an individual step 132 between the uppermost step 132 and the lowermost step 132).

In some embodiments, one or more of the conductive contact structures 142 in a first row 160 have substantially the same vertical height as one or more additional conductive contact structure 142 in a second row 162 neighboring the first row 160 within a single vertical level 152 of the vertical stack structure 122. Some of the conductive contact structures 142 on the steps 132 of the staircase structures 130 may be electrically isolated from one another by the first portions 158a of the isolation structures 158, as shown in FIG. 2I. Optionally, some of the conductive contact structures 142 on the steps 132 of the staircase structures 130 may be electrically isolated from one another by additional isolation structures (e.g., additional dielectric filled slots), as described in further detail below.

FIG. 2J illustrates a simplified top-down view of a region J depicted in FIG. 2I by way of a dashed box. For clarity and ease of understanding the drawings and associated description, some features (e.g., materials, structures, regions) of the microelectronic device structure 100 at the processing stage depicted in FIG. 2I, including some materials of the vertical stack structure 122, are omitted from FIG. 2J.

During formation of the second conductive structures 140, sacrificial portions (e.g., end portions 164) of the second conductive structures 140 may initially be formed to extend in the Y-direction and intervene between (e.g., connect) the first portions 140a of neighboring second conductive structures 140 to one another. In some embodiments, the end portions 164 may be separated from (e.g., electrically isolated from) the neighboring second conductive structures 140 (e.g., the first portions 140a thereof) proximate a perimeter (e.g., outer horizontal boundaries) of the vertical stack structure 122. For example, dielectric filled structures 166 (e.g., deep trench isolation structures) may be formed to extend in the Y-direction proximal the end portions 164 of the second conductive structures 140, separating the first portions 140a and, thus, the neighboring second conductive structures 140 from one another. As shown in FIG. 2J, the dielectric filled structures 166 may be formed on opposing sides of the second portions 158b of the isolation structures 158 and intersecting the first portions 158a thereof. Thus, elongated portions of the dielectric filled structures 166 may be substantially parallel to each of the second portions 158b of the isolation structures 158 and the second portions 140b of the second conductive structures 140.

In addition, support structures 168 (e.g., dielectric filled support structures) may, optionally, be formed between neighboring conductive contact structures 142 of individual rows 160, 162. For example, the support structures 168 may be formed to extend in the X-direction and separate (e.g., electrically isolate) the conductive contact structures 142 horizontally neighboring one another in the Y-direction. As shown in FIG. 2J, one or more (e.g., multiple) of the support structures 168 may be formed on opposing sides of the first portions 158a of the isolation structures 158 and may intersect the second portion 158b thereof. Thus, elongated portions of the support structures 168 may be substantially parallel to each of the first portions 158a of the isolation structures 158 and the first portions 140a of the second conductive structures 140.

Upper surfaces of the dielectric filled structures 166 and the support structures 168 may be substantially coplanar with one another, and lower surfaces of the dielectric filled structures 166 and the support structures 168 may be substantially coplanar with one another. Accordingly, the dielectric filled structures 166 may have about a same height as the support structures 168. The dielectric filled structures 166 and the support structures 168 may be individually formed of and include, for example, an insulative material, such as one or more of the materials described above with reference to the isolation structures 158 (e.g., SiO₂). In some embodiments, the support structures 168 may be formed during (e.g., substantially simultaneous with) formation of the dielectric filled structures 166 to reduce manufacturing costs. Further, one or more of the dielectric filled structures 166 and the support structures 168 may, for example, be configured and positioned to provide support to the vertical stack structure 122 proximal the second conductive structures 140 and the staircase structures 130 (FIG. 2I).

Referring to FIG. 2K, the microelectronic device structure 100 may be formed to include additional vertical stack structures 122 horizontally neighboring one another. The microelectronic device structure 100 including multiple (e.g., two) of the vertical stack structures 122 is shown schematically in FIG. 2K. For example, the vertical stack structures 122 may individually include the first staircase region 104a at a first horizontal end (e.g., in the X-direction) and include the second staircase region 104b at a second horizontal end (e.g., in the X-direction) opposite the first horizontal end. For clarity and ease of understanding the description, FIG. 2K does not illustrate other components of the microelectronic device structure 100, such as the vertical stacks of memory cells 108 (FIG. 1A) within the array region 102.

As shown in FIG. 2K, two of the vertical stack structures 122, for example, may horizontally neighbor one another in the X-direction. The vertical stack structures 122 may be arranged in a mirror pattern that is substantially symmetric to another with respect to a centerline (shown in dashed lines) at substantial equal distances between the array regions 102 of the horizontally neighboring vertical stack structures 122. For example, one of the first staircase regions 104a may be located at the first horizontal end of one of the vertical stack structures 122 and one of the second staircase regions 104b may be located at the second horizontal end thereof. In addition, a horizontally neighboring vertical stack structure 122 may include one of the first staircase regions 104a located at the second horizontal end thereof and one of the second staircase regions 104b located at the first horizontal end thereof, such that two of the second staircase regions 104b are adjacent to (e.g., horizontally neighboring) one another and proximal the centerline between the neighboring vertical stack structures 122.

A distance N between the array regions 102 of the horizontally neighboring vertical stack structures 122 may be substantially equally divided between the horizontally neighboring second staircase regions 104b, for example, such that each second staircase region 104b spans half of the distance N (e.g., N/2) between the array regions 102 of the neighboring vertical stack structures 122. In other regions of the microelectronic device structure 100, two of the first staircase region 104a may be adjacent to (e.g., horizontally neighboring) one another and proximal an additional centerline between neighboring vertical stack structures 122.

Referring to FIG. 2I, in combination with FIG. 2K, a configuration of the conductive contact structures 142 of the staircase structures 130 within the first staircase regions 104a may differ from a configuration of additional conductive contact structures 142 of the staircase structures 130 within the second staircase regions 104b. For example, the staircase structures 130 of the vertical stack structures 122 within the first staircase regions 104a may include the conductive contact structures 142 on even numbered steps 132 and additional staircase structures 130 within the second staircase regions 104b may include the conductive contact structures 142 on odd numbered steps 132, as described above. The staircase regions 104 horizontally neighboring (e.g., in the X-direction) the array regions 102 of the vertical stack structures 122 may alternate between a first configuration and a second configuration of the conductive contact structures 142 on the steps 132 of the staircase structures 130, with two of the staircase regions 104 (e.g., the first staircase regions 104a, the second staircase region 104b) of similar configurations horizontally neighboring one another. In additional embodiments, the configurations of the first staircase region 104a and the second staircase region 104b may be substantially the same as one another. Since the staircase structures 130 facilitate a reduced area of the microelectronic device structure 100, a horizontal area allocated to the staircase regions 104 including the staircase structures 130 may be reduced compared to staircase regions of conventional microelectronic device structures.

Thus, in accordance with some embodiments, a microelectronic device comprises a stack structure comprising an array region comprising first conductive structures vertically spaced from one another, and a staircase region horizontally neighboring the array region and comprising second conductive structures vertically spaced from one another and coupled to the first conductive structures. The second conductive structures individually comprise portions extending in a first horizontal direction, and additional portions extending in a second horizontal direction transverse to the first horizontal direction. The staircase region comprises staircase structures having steps partially defined by edges of the second conductive structures. Some of the steps extend in the first horizontal direction and some others of the steps extend in the second horizontal direction.

Furthermore, in accordance with additional embodiments of the disclosure, a memory device comprises vertical stacks of dynamic random access memory (DRAM) cells within an array region. Each of the DRAM cells comprises a storage device horizontally neighboring an access device. The memory device comprises first conductive lines extending in a first horizontal direction within the array region and operatively associated with the vertical stacks of DRAM cells, and second conductive lines external to the array region and coupled to the first conductive lines. The second conductive lines individually comprise first portions extending in the first horizontal direction, and second portions integral and continuous with the first portions and extending in a second horizontal direction orthogonal to the first horizontal direction. The memory device comprises conductive contacts in contact with staircase structures having horizontally curved steps partially defined by horizontal ends of the second conductive lines. The conductive structures comprise first rows of the conductive contacts extending in the second horizontal direction, and second rows of the conductive contacts extending in the second horizontal direction and substantially aligned with the first rows of the conductive contacts in the first horizontally direction.

Moreover, in accordance with some embodiments of the disclosure, a method of forming a microelectronic device comprises forming a preliminary stack structure comprising a vertically alternating sequence of insulative material and sacrificial material arranged in preliminary tiers. The preliminary stack structure includes an array region and a staircase region horizontally neighboring the array region. The method comprises forming staircase structures within the staircase region of the preliminary stack structure and individually having steps defined by horizontal edges of the preliminary tiers. The staircase structures comprise partially curved horizontal cross-sectional shapes at different vertical elevations thereof. The method comprises replacing portions of the sacrificial material within the array region with first conductive structures, and replacing additional portions of the sacrificial material within the staircase region with second conductive structures individually aligned with and coupled to the first conductive structures. The second conductive structures individually comprise portions extending in a first horizontal direction, and additional portions extending in a second horizontal direction transverse to the first horizontal direction.

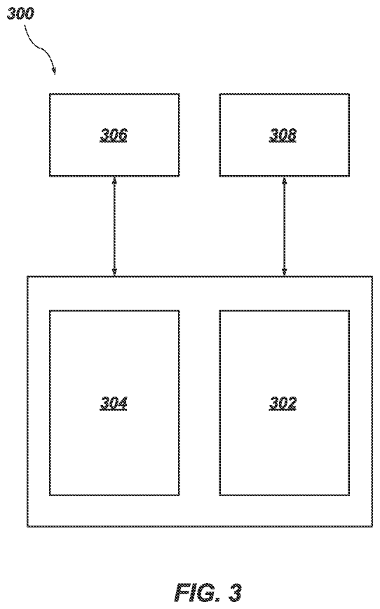

Structures, assemblies, and devices in accordance with embodiments of the disclosure may be included in electronic systems of the disclosure. For example, FIG. 3 is a block diagram of an illustrative electronic system 300 according to embodiments of disclosure. The electronic system 300 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The electronic system 300 includes at least one memory device 302. The memory device 302 may comprise, for example, an embodiment of one or more of a microelectronic device structure, a microelectronic device structure assembly, a relatively larger microelectronic device structure assembly, and a microelectronic device previously described herein with reference to FIGS. 1A through 2K. The electronic system 300 may further include at least one electronic signal processor device 304 (often referred to as a “microprocessor”). The electronic signal processor device 304 may, optionally, include an embodiment of one or more of a microelectronic device structure, a microelectronic device structure assembly, a relatively larger microelectronic device structure assembly, and a microelectronic device previously described herein with reference to FIGS. 1A through 2K. While the memory device 302 and the electronic signal processor device 304 are depicted as two (2) separate devices in FIG. 3, in additional embodiments, a single (e.g., only one) memory/processor device having the functionalities of the memory device 302 and the electronic signal processor device 304 is included in the electronic system 300. In such embodiments, the memory/processor device may include one or more of a microelectronic device structure, a microelectronic device structure assembly, a relatively larger microelectronic device structure assembly, and a microelectronic device previously described herein with reference to FIGS. 1A through 2K. The electronic system 300 may further include one or more input devices 306 for inputting information into the electronic system 300 by a user, such as, for example, a mouse or other pointing device, a keyboard, a touchpad, a button, or a control panel. The electronic system 300 may further include one or more output devices 308 for outputting information (e.g., visual or audio output) to a user such as, for example, one or more of a monitor, a display, a printer, an audio output jack, and a speaker. In some embodiments, the input device 306 and the output device 308 may comprise a single touchscreen device that can be used both to input information to the electronic system 300 and to output visual information to a user. The input device 306 and the output device 308 may communicate electrically with one or more of the memory device 302 and the electronic signal processor device 304.

Thus, in accordance with embodiments of the disclosure, an electronic system comprises a processor operably coupled to an input device and an output device, and a memory device operably coupled to the processor. The memory device comprises a stack structure comprising vertical stacks of memory cells, and staircase structures within the stack structure and horizontally neighboring to the vertical stacks of memory cells. The staircase structures individually comprise steps having at least partially curved horizontal cross-sectional shapes. The memory device comprises non-linear conductive lines partially defining the steps of the staircase structures. Two of the non-linear conductive lines are associated with one of the staircase structures.

While certain illustrative embodiments have been described in connection with the figures, those of ordinary skill in the art will recognize and appreciate that embodiments encompassed by the disclosure are not limited to those embodiments explicitly shown and described herein. Rather, many additions, deletions, and modifications to the embodiments described herein may be made without departing from the scope of embodiments encompassed by the disclosure, such as those hereinafter claimed, including legal equivalents. In addition, features from one disclosed embodiment may be combined with features of another disclosed embodiment while still being encompassed within the scope of the disclosure.

What is claimed is:

1. A microelectronic device, comprising:
a stack structure comprising:
an array region comprising first conductive structures vertically spaced from one another; and
a staircase region horizontally neighboring the array region and comprising:
second conductive structures vertically spaced from one another and coupled to the first conductive structures, the second conductive structures individually comprising:
portions extending in a first horizontal direction; and
additional portions extending in a second horizontal direction transverse to the first horizontal direction; and
staircase structures having steps partially defined by edges of the second conductive structures, some of the steps extending in the first horizontal direction and some others of the steps extending in the second horizontal direction.

2. The microelectronic device of claim 1, further comprising conductive contacts on the steps of the staircase structures, the conductive contacts arranged in rows extending in the second horizontal direction.

3. The microelectronic device of claim 2, wherein the staircase structures individually have two or more of the conductive contacts on each vertical level of the steps thereof, the conductive contacts on respective vertical levels electrically isolated from one another.

4. The microelectronic device of claim 1, wherein the staircase structures individually exhibit one or more partially closed curve horizontal cross-sectional shapes.

5. The microelectronic device of claim 1, wherein at least two horizontal portions of one of the staircase structures are located on at least two different vertical levels within the stack structure than one another, a group of the second conductive structures within one of the at least two different vertical levels vertically underlying an additional group of the second conductive structures within another one of the at least two different vertical levels.

6. The microelectronic device of claim 1, wherein each of the staircase structures is horizontally split between at least two vertical levels of the stack structure, each of the at least two vertical levels of the stack structure vertically spanning a different group of the second conductive structures and each of the at least two vertical levels of the stack structure.

7. The microelectronic device of claim 1, wherein the steps of at least one of the staircase structures individually have an at least partially curved horizontal shape comprising:
a first portion extending in the first horizontal direction;
a second portion extending in the second horizontal direction transverse to the first horizontal direction; and
at least one additional portion between the first portion and the second portion and extending at an acute angle relative to the first horizontal direction and the second horizontal direction.

8. The microelectronic device of claim 1, further comprising vertical stacks of memory cells within the array region of the stack structure, each of the vertical stacks of memory cells comprising:
a vertical stack of access devices; and
a vertical stack of storage devices horizontally neighboring the vertical stack of access devices.

9. A memory device, comprising:
vertical stacks of dynamic random access memory (DRAM) cells within an array region, each of the DRAM cells comprising a storage device horizontally neighboring an access device;
first conductive lines extending in a first horizontal direction within the array region and operatively associated with the vertical stacks of DRAM cells;
second conductive lines external to the array region and coupled to the first conductive lines, the second conductive lines individually comprising:
first portions extending in the first horizontal direction; and
second portions integral and continuous with the first portions and extending in a second horizontal direction orthogonal to the first horizontal direction; and
conductive contacts in contact with staircase structures having horizontally curved steps partially defined by horizontal ends of the second conductive lines, the conductive contacts comprising:
first rows of the conductive contacts extending in the second horizontal direction; and
second rows of the conductive contacts extending in the second horizontal direction and substantially aligned with the first rows of the conductive contacts in the first horizontally direction.

10. The memory device of claim 9, wherein the horizontally curved steps of the staircase structures individually have partially arcuate horizontal boundaries.

11. The memory device of claim 9, wherein the conductive contacts are operably coupled to the access device of each of the DRAM cells by means of the first conductive lines and the second conductive lines.

12. The memory device of claim 9, wherein one of the conductive contacts in a first row of the conductive contacts has substantially the same vertical height as an additional one of conductive contacts in a second row of the conductive contacts horizontally neighboring the first row of the conductive contacts.

13. The memory device of claim 9, wherein the staircase structures individual have different closed curve horizontal cross-sectional shapes at different vertical elevations thereof.

14. The memory device of claim 9, wherein at least some of the second conductive lines are oriented substantially symmetrically about a horizontal midpoint between neighboring second conductive lines.

15. The memory device of claim 9, further comprising isolation structures horizontally neighboring the second conductive lines, the isolation structures individually comprising:
first portions horizontally between parallel extending segments of the second conductive lines; and
second portions horizontally intersecting the first portions and horizontally extending substantially parallel to additional segments of the second conductive lines interleaved between the parallel extending segments of the second conductive lines.

16. The memory device of claim 9, further comprising a first staircase region horizontally adjacent to the array region and a second staircase region horizontally adjacent to the array region on a side opposite the first staircase region, a configuration of a group of the conductive contacts within the first staircase region differing from a configuration of an additional group of the conductive contacts within the second staircase region.

17. A method of forming a microelectronic device, the method comprising:
forming a preliminary stack structure comprising a vertically alternating sequence of insulative material and sacrificial material arranged in preliminary tiers, the preliminary stack structure including an array region and a staircase region horizontally neighboring the array region;
forming staircase structures within the staircase region of the preliminary stack structure and individually having steps defined by horizontal edges of the preliminary tiers, the staircase structures comprising partially curved horizontal cross-sectional shapes at different vertical elevations thereof;
replacing portions of the sacrificial material within the array region with first conductive structures; and
replacing additional portions of the sacrificial material within the staircase region with second conductive structures individually aligned with and coupled to the first conductive structures, the second conductive structures individually comprising:
portions extending in a first horizontal direction; and
additional portions extending in a second horizontal direction transverse to the first horizontal direction.

18. The method of claim 17, wherein forming the staircase structures comprises:
forming preliminary staircase structures individually having elliptical horizontal cross-sectional stapes; and
vertically extending at least some portions of at least some of the preliminary staircase structures to relatively vertically lower positions within the preliminary stack structure.

19. The method of claim 18, wherein forming the staircase structures comprises:
removing material of the preliminary stack structure to form central openings arranged in a hexagonal pattern; and
removing additional material of the preliminary stack structure to form a series of preliminary steps of preliminary staircase structures progressively outward and substantially surrounding the central openings; and
vertically extending portions of the preliminary staircase structures relatively deeper into the preliminary stack structure than other portions of the preliminary staircase structures.

20. The method of claim 17, further comprising forming linear portions of the first conductive structures within the array region substantially simultaneously with forming non-linear portions of the second conductive structures within the staircase region.

21. An electronic system, comprising:
a processor operably coupled to an input device and an output device; and
a memory device operably coupled to the processor, the memory device comprising:
a stack structure comprising vertical stacks of memory cells;
staircase structures within the stack structure and horizontally neighboring to the vertical stacks of memory cells, the staircase structures individually comprising steps having at least partially curved horizontal cross-sectional shapes; and
non-linear conductive lines partially defining the steps of the staircase structures, two of the non-linear conductive lines associated with one of the staircase structures.

22. The electronic system of claim 21, wherein:
the staircase structures are spaced from one another in a first horizontal direction and in a second horizontal direction; and
rows of the staircase structures are horizontally staggered from one another, such that a first row of the staircase structures is offset in the first horizontal direction and in the second horizontal direction from a second row of the staircase structures horizontally neighboring the first row.

23. The electronic system of claim 21, wherein portions of the non-linear conductive lines defining uppermost steps of some of the staircase structures comprise bridge portions common to three or more of the some of the staircase structures.

24. The electronic system of claim 21, wherein the non-linear conductive lines comprise first linear portions horizontally interleaved with second linear portions, at least some of the first linear portions and at least some of the second linear portions having substantially equal lengths as one another.

25. The electronic system of claim 21, wherein the memory device is a three-dimensional (3D) dynamic random access memory (DRAM) device.
